(19) United States
(12) Patent Application Publication
(10) Pub. No.: US 2010/0117070 A1
(43) Pub. Date: May 13, 2010

(54) TEXTURED SEMICONDUCTOR LIGHT-EMITTING DEVICES

(75) Inventors: Bunmi T. ADEKORE, Arlington, MA (US); Jonathan PIERCE, Piscataway, NJ (US); George B. KENNEY, Medfield, MA (US); Gianni TARASCHI, Somerville, MA (US)

Correspondence Address: WILMERHALE/BOSTON, 60 STATE STREET, BOSTON, MA, 02109, US

(73) Assignee: LUMENZ LLC, Boston, MA (US)

(21) Appl. No.: 12/562,941

(22) Filed: Sep. 18, 2009

Related U.S. Application Data
(60) Provisional application No. 61/098,097, filed on Sep. 18, 2008.

(51) Int. Cl. H01L 33/00; H01L 21/34

(52) U.S. Cl. 257/43; 438/29; 257/E33.019; 257/E21.459

(57) ABSTRACT

A light-emitting device, such as a light-emitting diode (LED), includes a substrate including a ZnO-based material, and a structure disposed on a first side of the substrate. The structure includes a plurality of semiconductor layers and an active layer disposed between the plurality of semiconductor layers. The device further includes at least one textured light emission surface arranged to extract at least some light generated within the device.

### CROSS-REFERENCE TO RELATED APPLICATIONS

This application claims priority to U.S. Provisional Application No. 61/098,097, filed on Sep. 18, 2008, which is incorporated herein by reference in its entirety.

### FIELD OF INVENTION

The invention relates generally to light-emitting devices and methods of making the same, and more specifically to light-emitting devices and methods including textured layer(s) and/or oxide-based semiconductors, such as metal oxide semiconductors, including but not limited to ZnO-based semiconductors.

### BACKGROUND

Semiconductor light-emitting devices, such as light-emitting diodes (LEDs) and laser diodes (LDs), can serve as light sources that can be efficient, robust, and environmentally friendly. Light-emitting devices emitting short wavelengths such as blue and green light have been created using Group III-nitride materials systems, such as the AlInGaN materials system. At the longer wavelength end of the spectrum, light-emitting devices emitting red, orange, and yellow light have been fabricated using Group III-phosphide materials systems, such as the AlInGaP materials system.

Although these material systems have enabled LEDs and LDs that emit light across the visible spectrum, the unacceptably high cost and low material quality of Group III-nitride light-emitting devices impedes the further proliferation of semiconductor light-emitting devices in many illumination applications, such as general lighting.

### SUMMARY OF INVENTION

In one aspect, a light-emitting device comprises a substrate comprising a ZnO-based material, and a structure disposed on a first side of the substrate, the structure comprising a plurality of semiconductor layers and an active layer disposed between the plurality of semiconductor layers. The device further comprises at least one textured light emission surface arranged to extract at least some light generated within the device.

In one aspect, a light-emitting device comprises a substrate comprising a ZnO-based material, and a structure disposed on a first side of the substrate, the structure comprising a plurality of semiconductor layers and an active layer disposed between the plurality of semiconductor layers. The device further comprises a textured reflective layer arranged to reflect at least some light generated within the device.

In one aspect, a light-emitting device comprises a structure comprising a plurality of semiconductor layers and an active layer disposed between the plurality of semiconductor layers, wherein the active layer comprises a ZnO-based semiconductor. The device further comprises at least one textured light emission surface arranged to extract at least some light generated within the device.

In one aspect, a light-emitting device comprises a structure comprising a plurality of semiconductor layers and an active layer disposed between the plurality of semiconductor layers, wherein the active layer comprises a ZnO-based semiconductor. The device further comprises a textured reflective layer arranged to reflect at least some light generated within the device.

In one aspect, a light-emitting device comprises a structure comprising a plurality of semiconductor layers and an active layer disposed between the plurality of semiconductor layers, wherein the plurality of semiconductor layers are formed of one or more ZnO-based semiconductors. The device further comprises at least one textured light emission surface arranged to extract at least some light generated within the device.

In one aspect, a light-emitting device comprises a structure comprising a plurality of semiconductor layers and an active layer disposed between the plurality of semiconductor layers, wherein the plurality of semiconductor layers are formed of one or more ZnO-based semiconductors. The device further comprises a textured reflective layer arranged to reflect at least some light generated within the device.

In one aspect, a light-emitting device comprises a structure comprising a plurality of semiconductor layers and an active layer disposed between the plurality of semiconductor layers, wherein the structure includes at least one textured monocrystalline ZnO-based layer.

In one aspect, a method of forming a device is provided. The method comprises providing a substrate, depositing a buffer layer on the substrate, and depositing at least one textured monocrystalline device layer on the buffer layer, wherein a surface morphology of the at least one textured monocrystalline device layer is at least partially determined by the buffer layer.

In one aspect, a light-emitting device comprises an n-type semiconductor layer, a p-type semiconductor layer, an active layer disposed between the n-type semiconductor layer and the p-type semiconductor layer, wherein the n-type semiconductor layer and the p-type semiconductor layer have a refractive index of less than 2.3 at a light emission wavelength of the active layer, and a textured monocrystalline layer disposed on the n-type semiconductor layer or the p-type semiconductor layer, wherein the textured monocrystalline layer has a refractive index of less than 2.3 at the light emission wavelength of the active layer.

In one aspect, a light-emitting device comprises an n-type semiconductor layer, a p-type semiconductor layer, an active layer disposed between the n-type semiconductor layer and the p-type semiconductor layer, and a monocrystalline transparent conductive oxide layer disposed adjacent the n-type semiconductor layer or the p-type semiconductor layer and configured to provide current spreading.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1A is a cross-sectional view of a light-emitting device including one or more textured layers according to one embodiment;

FIG. 1B is a cross-sectional view of a light-emitting device including one or more textured layers according to one embodiment;

FIGS. 2A-B are cross-sectional views of intermediate structures corresponding to a method for forming one or more textured layer(s) on a substrate according to one embodiment;

FIG. 3 is a cross-sectional view of a light-emitting device including one or more device layers deposited on a buffer according to one embodiment;

FIGS. 4A-B are cross-sectional views of intermediate structures corresponding to a method for forming one or more textured layer(s) on a buffer according to one embodiment;

FIG. 5A is a cross-sectional view of a light-emitting device including semiconductor cladding and contact layers on one or both sides of the active layer according to one embodiment;

FIG. 5B is a cross-sectional view of a light-emitting device including semiconductor cladding and contact layers on one or both sides of an active layer according to one embodiment;

FIG. 6A is a cross-sectional view of a light-emitting device having a lateral electrical contacting geometry according to one embodiment;

FIG. 6B is a cross-sectional view of a light-emitting device including a textured reflective layer according to one embodiment;

FIG. 6C is a cross-sectional view of a light-emitting device including a plurality of textured light emission surfaces according to one embodiment;

FIG. 6D is a top view of the light-emitting device of FIG. 6C according to one embodiment;

FIG. 6E is a cross-sectional view of a light-emitting device including a plurality of textured light emission surfaces and mounted in a flip-chip configuration according to one embodiment;

FIG. 7 is cross-sectional view of a light-emitting device including a substrate having a textured surface over which device epilayers is deposited according to one embodiment;

FIGS. 8A-C are cross-sectional views of intermediate structures corresponding to a method for forming one or more textured layer(s) on a substrate having a textured deposition surface according to one embodiment;

FIG. 9A is a cross-sectional view of a light-emitting device including a textured light emission surface according to one embodiment;

FIG. 9B is a cross-sectional view of a light-emitting device including a textured light emission surface according to one embodiment;

FIG. 9C is a cross-sectional view of a light-emitting device including a textured light emission surface according to one embodiment;

FIGS. 10A-C are cross-sectional views of intermediate structures corresponding to a method for forming a light-emitting device having a textured light emission surface according to one embodiment; and

FIG. 11 is a cross-sectional view of a light-emitting device including a textured reflective layer according to one embodiment.

### DETAILED DESCRIPTION

Reference now will be made in detail to the presently preferred embodiments of the invention. Such embodiments are provided by way of explanation of the invention, which is not intended to be limited thereto. In fact, those of ordinary skill in the art can appreciate upon reading the present specification and viewing the present drawings that various modifications and variations can be made.

Before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. Numerous embodiments are described in this patent application, and are presented for illustrative purposes only. The described embodiments are not intended to be limiting in any sense. The invention is widely applicable to numerous embodiments, as is readily apparent from the disclosure herein. Those skilled in the art will recognize that the present invention can be practiced with various modifications and alterations. Although particular features of the present invention can be described with reference to one or more particular embodiments or figures, it should be understood that such features are not limited to usage in the one or more particular embodiments or figures with reference to which they are described.

As such, those skilled in the art will appreciate that the conception, upon which this disclosure is based, can readily be utilized as a basis for the designing of other structures, methods and systems for carrying out the several purposes of the present invention. It is important, therefore, that the invention be regarded as including equivalent constructions to those described herein insofar as they do not depart from the spirit and scope of the present invention.

For example, the specific sequence of the described process can be altered so that certain processes are conducted in parallel or independent, with other processes, to the extent that the processes are not dependent upon each other. Thus, the specific order of steps described herein is not to be considered implying a specific sequence of steps to perform the process. Other alterations or modifications of the above processes are also contemplated. For example, further insubstantial approximations of the process and/or algorithms are also considered within the scope of the processes described herein.

In addition, features illustrated or described as part of one embodiment can be used on other embodiments to yield a still further embodiment. Additionally, certain features can be interchanged with similar devices or features not mentioned yet which perform the same or similar functions. It is therefore intended that such modifications and variations are included within the totality of the present invention.

Light-emitting devices and methods provided herein can alleviate some, if not many or all of the deficiencies of current LEDs. Device structures provided include or more textured layers, such as one or more textured light emission surfaces, a textured active layer, and/or one or more textured reflective layers. Textured layers can facilitate light extraction via the frustration of total internal reflection of light within the LED structure. The textured surface can have sufficient dimensions so as to enhance light extraction. In some embodiments, the textured light emission surface has a RMS roughness of between about 0.05 μm and about 5 μm, and preferably between about 0.1 μm and about 3 μm.

Some devices provided herein include textured monocrystalline layers (i.e., single crystal layers), and some light-emitting devices provided include one or more monocrystalline transparent conductive oxide layers, which can or can not be textured. As described further herein, texturing of layers is achieved during deposition of the layers and/or after the layers have been deposited.

In some devices described herein, ZnO-based materials can be employed to form part or the entire semiconductor portion of a light-emitting device, for example the LED semiconductor layers. Furthermore, in some instances a ZnO substrate can be used to provide a substrate on which LED layers can be deposited. Due to potentially low lattice mismatch between the substrate and epitaxial layers, such a substrate can enable the growth of low defect density monocrystalline epitaxial layers (e.g., ZnO-based epitaxial layers) that can enable efficient device performance. ZnO substrates can be optically transparent (e.g., to the wavelength of light emitted by the active layer and/or to all visible wavelengths) and, if desired, doped so as to be electrically conductive. Such a substrate can provide a low-cost substrate, which in addition to the potential low cost of the epitaxy sources for ZnO-based materials canfacilitate the production of affordable and efficient solid state lighting devices.

As will be understood, ZnO-based semiconductors are inherently n-type. As such, it should be understood that p-type ZnO-based semiconductors are extremely sensitive to the introduction of impurities (e.g., donor dopants) and/or defects (e.g., point defects such as interstitials, vacancies, and/or anti-sites) that can compensate the p-type dopants present in the layer and that can reduce or remove the p-type conductivity of the semiconductor. Consequently, as will be explained in detail herein, the deposition of layers as well as deposition conditions and fabrication processes must be chosen to protect p-type ZnO-based structures to allow for construction and maintenance of functional devices. Temperature windows and available materials for construction of ZnO-based semiconductors are limited.

ZnO-based materials include an oxide containing Zn, examples of which include oxides of Group IIA and/or Group IIB with Zn, in addition to ZnO itself. Specific examples of ZnO-based materials include ZnO, ZnMgO, ZnCaO, ZnBeO, ZnSrO, ZnBaO, ZnCdO, and alloys of these materials, such as MgCdZnO. Each of the above materials can be optionally alloyed with a Group VI element, such as Group VIA elements (e.g., Te, Se, and/or S).

In some embodiments, a ZnO-based material include alloying elements such as Group II elements (e.g., Mg, Be, Ca, Sr, Ba, Cd, or other related elements), Group VI elements (e.g., Te, Se, S, or other related elements) or combinations thereof. The alloying elements can enable the formation of a ternary or quaternary compound that can allow for greater flexibility in engineering the bandgap and/or lattice parameter(s) of the ZnO-based material, which can be useful in device structures that employ stacked semiconductor epitaxial layers having differing bandgaps (e.g., LEDs, LDs).

In some embodiments, alloying with an element on the oxygen sub-lattice can vary (e.g., decrease and/or increase) the bandgap of a ZnO-based material. Such alloying is described in PCT publication WO/2008/073469, filed Dec. 11, 2007 entitled “Zinc Oxide Multi-Junction Photovoltaic Cells and Optoelectronic Devices,” commonly owned by the assignee and herein incorporated by reference in its entirety. Alloying with an element on the oxygen sub-lattice can further vary (e.g., decrease or increase) the bandgap of the ZnO-based material beyond what can be achieved using only alloying with an element on the zinc sub-lattice (e.g., as a result of the solubility limit of the zinc sub-lattice element in ZnO). Oxygen sub-lattice alloying elements that can result in a variation of the bandgap of a ZnO-based material include Te, Se, and/or S. In some embodiments, bandgaps of less than about 3 eV can be achieved. In some embodiments, the bandgap of the alloy can be greater than about 2 eV and less than about 3 eV. In some embodiments, bandgaps of less than about 2 eV can be achieved. In some embodiments, the bandgap of the alloy can be greater than about 1 eV and less than about 2 eV.

A ZnO-based material can be a p-type conductivity semiconductor, an n-type conductivity semiconductor, or an intrinsic conductivity semiconductor. P-type dopants can be included in the ZnO-based material, including one or more suitable Group IA, IB, VA and/or VB elements, such as K, Au, Ag, N, P As, Sb and/or other appropriate elements. N-type dopants can be included in the ZnO-based material, including one or more suitable Group III elements (e.g., B, Al, Ga, In, and/or Tl) and/or Group VII elements (e.g., F, Cl, Br, I).

The doping of the ZnO layers can be of varying types. Co-doped compensated semiconductors (e.g., a ZnO-based semiconductor, a Group-III nitride semiconductor) include both n-type and p-type dopants. N-type co-doped compensated semiconductors can have a concentration of activated donors greater than a concentration of activated acceptors. P-type co-doped compensated semiconductors can have a concentration of activated acceptors greater than a concentration of activated donors. Intrinsic co-doped compensated semiconductors can have a concentration of activated acceptors about equal to a concentration of activated donors.

N-type, p-type, and intrinsic semiconductor layers can enable the formation of various semiconductor device structures, as described further below. In some of the device structures, semiconductor layers (e.g., active layer, one or more cladding layers, and/or one or more contact layers) or portions of the semiconductor layers can have an n-type conductivity, p-type conductivity, or intrinsic conductivity, whereby the intrinsic conductivity can be achieved via co-doping or via no intentional doping.

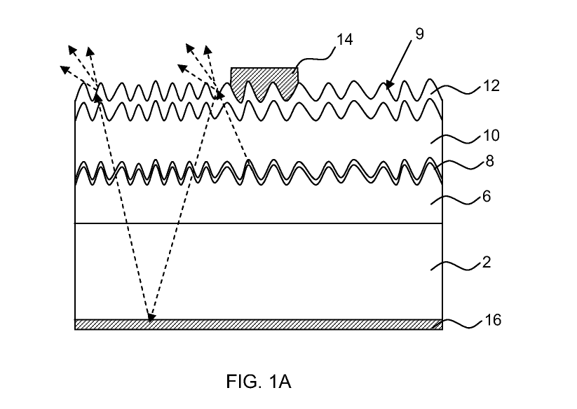

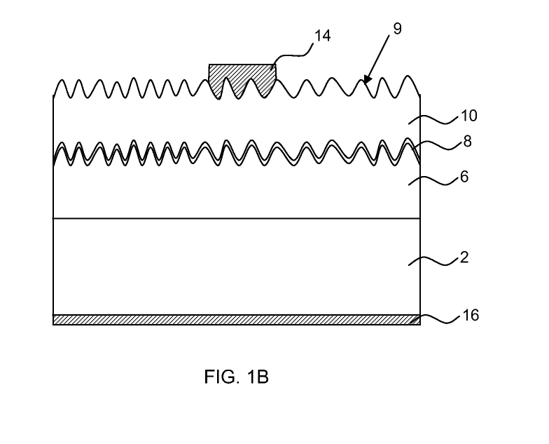

FIG. 1A is a cross-sectional view of a light-emitting device including one or more textured layers. In some embodiments, a light emission surface of the light-emitting device can be textured. Although the structure is described in the context of a light-emitting device, it should be appreciated that such a structure or similar structures can also be used in other devices such as other opto-electronic, photonic, or electronic devices (e.g., photodiodes, photovoltaics, excitonic devices, excitonic integrated circuits, excitonic light switches, transistors).

The light-emitting device includes a structure comprising a plurality of semiconductor layers and an active layer 8 disposed between the plurality of semiconductor layers. The plurality of semiconductor layers can comprise a first conductivity-type semiconductor layer 6 (e.g., n-type or p-type) and a second conductivity-type semiconductor layer 10 (e.g., p-type or n-type), and the active layer 8 can be disposed between semiconductor layer 6 and semiconductor layer 10.

The plurality of semiconductor layers (e.g., layers 6 and 10) and/or the active layer 8 can have a hexagonal crystal structure (e.g., a wurtzite crystal structure), examples of which include ZnO-based semiconductors or Group III-nitride semiconductors. The plurality of semiconductor layers (e.g., layers 6 and 10) and the active layer 8 can be epitaxially deposited on a substrate 2 that can also have a hexagonal crystal structure (e.g., a wurtzite crystal structure). In some embodiments, the plurality of semiconductor layers (e.g., layers 6 and 10) and the active layer 8 form interfaces that are oriented substantially parallel to a non-polar plane of the crystal structure (e.g., m-plane or a-plane of a wurtzite crystal structure). In other embodiments, the plurality of semiconductor layers (e.g., layers 6 and 10) and the active layer 8 form interfaces that are oriented substantially parallel to a semi-polar plane of the crystal structure.

One or more (e.g., all) of the device layers can be formed of one or more ZnO-based materials. In some embodiments, at least one of the active layer 8, the n-type semiconductor layer, and the p-type semiconductor layer can be formed of a ZnO-based semiconductor. The plurality of semiconductor layers (e.g., n-type and p-type semiconductor layers 6 and 10) can be formed of one or more ZnO-based semiconductors. The active layer 8 can be formed of one or more ZnO-based semiconductors. In embodiments where the entire semiconductor device layer is formed of ZnO-based materials, each of the active layer 8, the n-type semiconductor layer, and the p-type semiconductor layer can be formed of one or more ZnO-based semiconductors. Alternatively, at least one layer of the device structure can be formed of one or more Group III-nitride semiconductors. For example, the plurality of semiconductor layers (e.g., layers 6 and 10) and/or the active layer can be formed of one or more Group III-nitride semiconductors.

It should be appreciated that since ZnO-based materials have a natural tendency to form multi-grain nanostructures or microstructures, electrical contacting of such structures can be problematic. For example, ZnO-based semiconductor layers epitaxially grown on polar planes of ZnO-based (and other wurtzite) substrates exhibit granular and/or columnar growth patterns. In contrast, the formation of monocrystalline ZnO-based layer(s) can alleviate these problems while at the same time avoiding any defect-related problems associated with polycrystalline and/or amorphous ZnO-based layers. For example, ZnO-based monocrystalline and amorphous ZnO-based layers grown on non-polar and semi-polar planes of ZnO-based (and other wurtzite) substrates exhibit contiguous or non-granular growth patterns. Furthermore, a textured monocrystalline or amorphous layer can be textured to provide a textured monocrystalline or amorphous ZnO-based layer can be employed in devices, such as light-emitting devices (e.g., LEDs), so as to facilitate light extraction or collection. In some embodiments, a light-emitting emitting device (e.g., LED) including a textured layer, such as a textured light emission surface, can facilitate the extraction of light generated within the device structure (e.g., by the active layer) via the frustration of total internal reflection within the device structure.

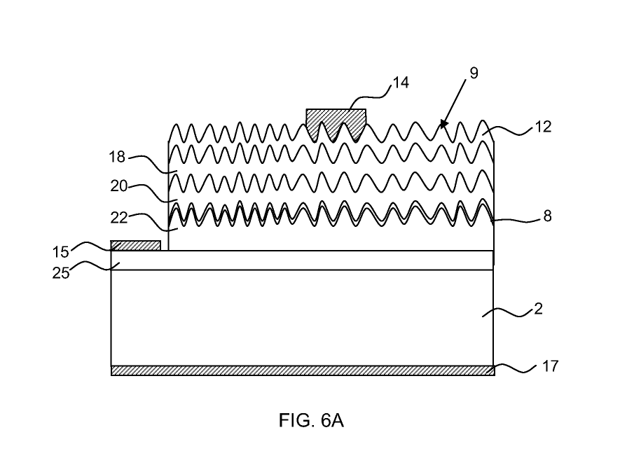

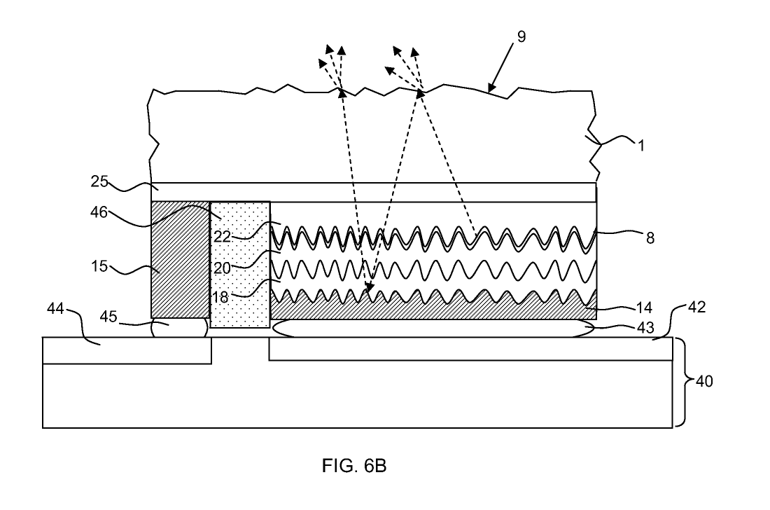

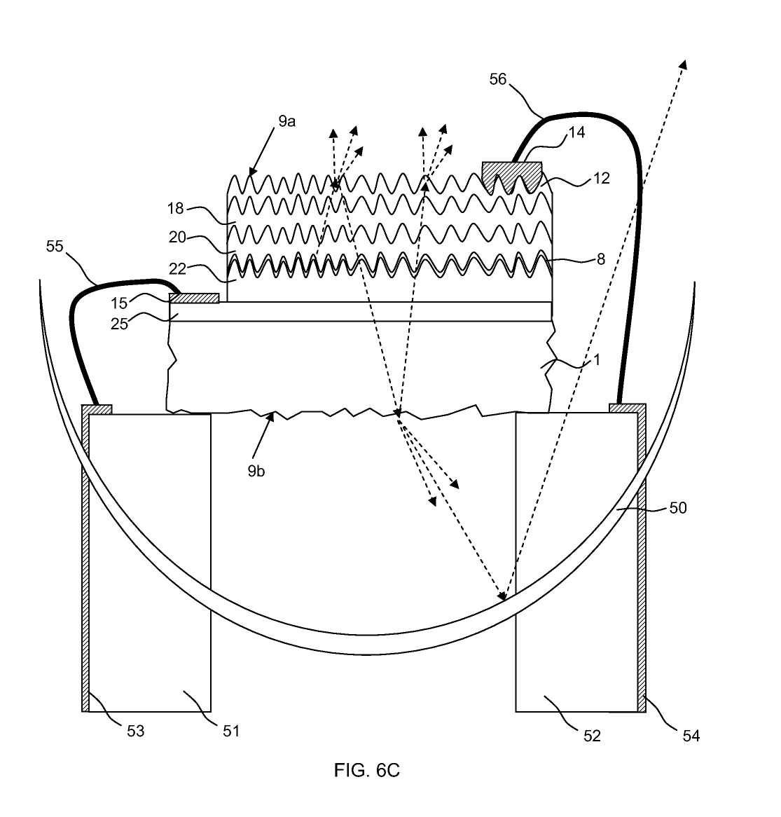

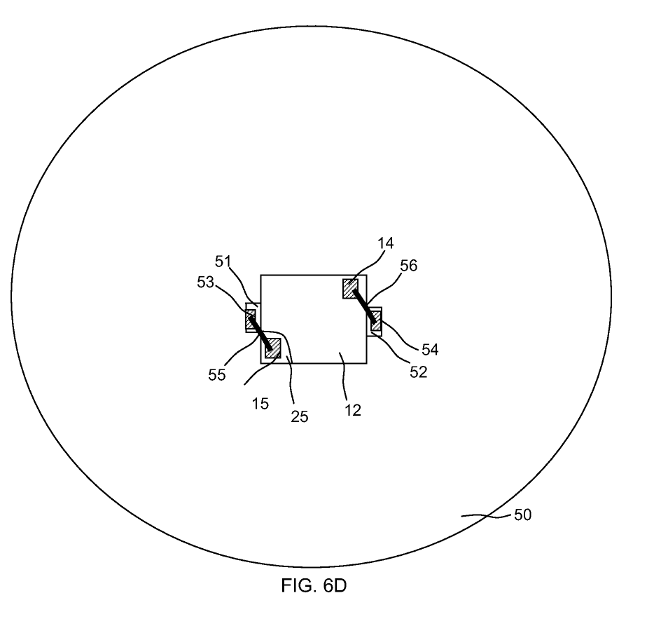

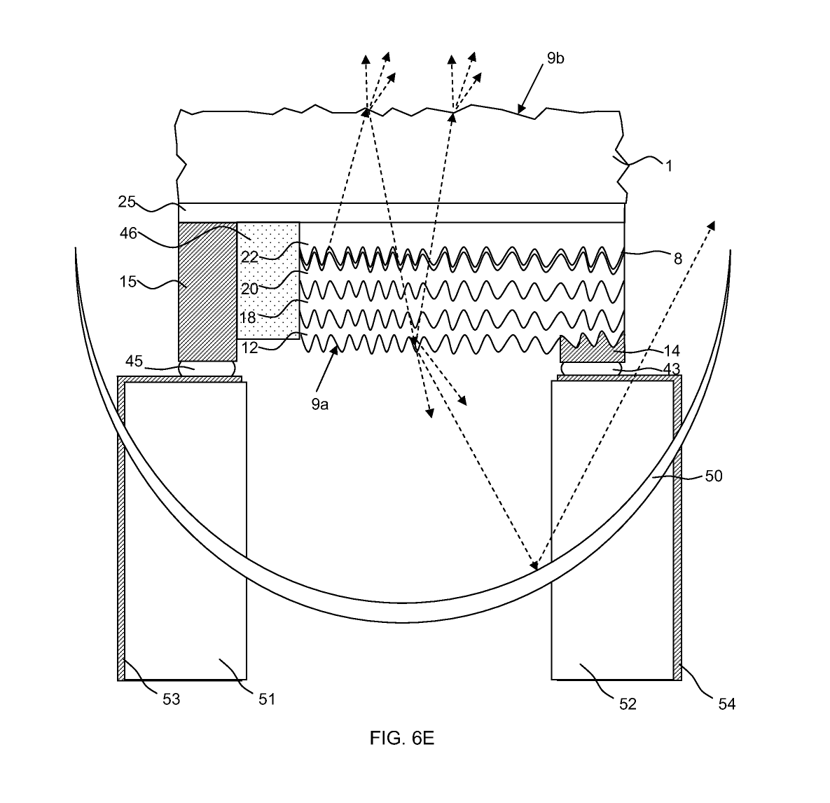

In some embodiments, a light-emitting device includes at least one textured monocrystalline ZnO-based layer. In some embodiments, at least one of the active layer 8, the n-type semiconductor layer, and the p-type semiconductor layer comprises a textured monocrystalline ZnO-based layer. The plurality of semiconductor layers (e.g., n-type and p-type semiconductor layers 6 and 10) include at least one textured monocrystalline ZnO-based layer. Alternatively, or additionally, active layer 8 include at least one textured monocrystalline ZnO-based layer. The plurality of semiconductor layers 6 and 10 and the active layer 8 can be deposited on a first side of the substrate 2. Substrate 2 include a second side opposite the first side of the substrate 2, where the second side of the substrate 2 can be textured and can serve as a textured light emission surface, as described further below in relation of the device shown in FIG. 6B.

In some embodiments, the n-type semiconductor layer and/or the p-type semiconductor layer (e.g., layers 6 and/or 10) can have a refractive index of less than 2.3 at a light emission wavelength of the active layer 8. Such a refractive index can be achieved via the use of various ZnO-based materials, in contract to presently popular light-emitting device materials (e.g., GaN-based materials) that have larger a refractive index of about 2.5. For example, ZnO itself has a refractive index of about 2.1 at a wavelength of about 450 nm. Such a low refractive index can provide a great advantage and greatly facilitate light extraction efficiency.

A textured monocrystalline layer (e.g., a ZnO-based layer) can be disposed on the n-type semiconductor layer or the p-type semiconductor layer (e.g., layers 6 or 10). The textured monocrystalline layer can be formed of one or more materials (e.g., ZnO-based materials) having a bandgap larger than the bandgap of the active layer, larger than the bandgap of quantum wells in the active layer, and/or larger than semiconductor layers, thereby minimizing the absorption of generated light by the textured monocrystalline layer. The textured monocrystalline layer can have a refractive index of less than 2.3 at the light emission wavelength of the active layer 8. The textured monocrystalline layer can have a refractive index of greater than 1.9 at the light emission wavelength of the active layer 8. The textured monocrystalline layer can have a refractive index that is substantially the same (i.e., having a refractive index difference of less than about ±0.3) as the refractive index of the n-type semiconductor layer or the p-type semiconductor layer on which it can be disposed. In some embodiments, the light emission wavelength of the active layer 8, which can be a peak emission wavelength, is greater than about 360 nm (e.g., greater that about 400 nm, greater than about 450 nm). In some embodiments, the light emission wavelength of the active layer 8, which can be a peak emission wavelength, is less than about 600 nm (e.g., less that about 500 nm, less than about 450 nm).

The textured monocrystalline layer include a transparent material. Examples of transparent materials include ZnO-based materials, MgO, ZnS, CdS, In₂O₃, TiO₂, PbO, NiO, ZnSnO, indium tin oxide (ITO), or any combination thereof. The textured monocrystalline layer include a transparent oxide. Examples of transparent oxides include ZnO-based materials, MgO, In₂O₃, TiO₂, PbO, NiO, ZnSnO, indium tin oxide (ITO), or any combination thereof. The textured monocrystalline layer include a transparent conductive material, such as a transparent conductive oxide. Examples of transparent conductive oxides include ZnO-based materials, In₂O₃, indium tin oxide (ITO), or any combination thereof. The textured monocrystalline layer include n-type and/or p-type semiconductor materials (e.g., an n-type and/or p-type ZnO-based semiconductor). In some embodiments, the textured monocrystalline layer can be the substrate 2 (e.g., having backside texturing) on which the n-type semiconductor layer, the p-type semiconductor layer, and the active layer 8 are disposed. The textured monocrystalline layer can have a low dislocation density of less than about 10⁶ cm⁻²(e.g., less than about 10⁵ cm⁻², less than about 10⁴ cm⁻², less than about 10³ cm⁻², less than about 10² cm²). Such a low dislocation density can be a result of low lattice mismatch between the textured monocrystalline layer and the layer on which it is deposited.

In some embodiments, a transparent conductive layer 12 can be disposed on second conductivity-type semiconductor layer 10. A first electrode 14 can be disposed on transparent conductive layer 12. A second electrode 16 can be formed on the backside of substrate 2, for embodiments where the substrate is electrically conductive (e.g., n-type or p-type) and thereby can serve as a conductive path to semiconductor layer 6. In some embodiments, the backside of substrate 2 can be textured (e.g., roughened and/or patterned) prior to the formation of electrode 16 on the substrate backside, thereby allowing for the formation of a textured reflective layer on the backside of the substrate. Examples of texturing processes, such as roughening etches and/or patterning, are discussed in further detail below (e.g., in relation to FIG. 6B).

Semiconductor layer 6 can be an n-type layer and semiconductor layer 10 can be a p-type layer. Alternatively, semiconductor layer 6 can be a p-type layer and semiconductor layer 10 can be an n-type layer. The thickness of semiconductor layer 6 and/or semiconductor layer 10 can range from about 0.5 microns to about 3 microns, however any other suitable thickness can also be used. Doping of semiconductor layer 6 and/or semiconductor layer 10 can be achieved with various dopant elements for ZnO-based materials, as described in detail below. For example, doping one or more suitable Group IA, IB, VA and/or VB elements, such as K, Au, Ag, N, P As, Sb and/or other appropriate elements, can be used to achieve p-type conductivity. Doping one or more suitable Group III elements (e.g., B, Al, Ga, In, and/or Tl) and/or Group VII elements (e.g., F, Cl, Br, I) can be used to achieve n-type conductivity. The doping concentration of part or all of semiconductor layer 6 and/or semiconductor layer 10 can range between from about 10¹⁶ cm⁻³ to about 10²¹ cm⁻³, however any other suitable doping concentration can be used.

One or both of semiconductor layer 6 and semiconductor layer 10 include ZnO-based materials, such as one or more ZnO-based epitaxial layers. In some embodiment, the entire semiconductor layer 6 and/or the entire semiconductor layer 10 are formed of one or more ZnO-based materials, such as one or more ZnO-based epitaxial layers. Such materials include ZnO itself and/or ZnO-based alloys including Mg, Ca, Be, Sr, Ba, Cd, Se, Te, and/or S.

In some embodiments, semiconductor layer 6 and/or semiconductor layer 10 can be textured. In some embodiments, semiconductor layer 6 and/or semiconductor layer 10 include a textured monocrystalline layer. A textured surface morphology of a layer can be formed during and/or after deposition of the layer. Texturing a layer during deposition can involve the use of appropriate deposition conditions, such as temperature, so as to produce a textured layer during the deposition process. Texturing a layer after deposition can involve roughening (e.g., via one or more wet and/or dry etches) and/or patterning (e.g., via a lithography process) the deposited layer. In some embodiments, semiconductor layers 6 and/or 10 can comprise a textured ZnO-based material layer, such as a textured monocrystalline ZnO-based layer.

Active layer 8 include one or more layers having a different energy bandgap than the adjacent semiconductor layers, thereby forming a double heterostructure. Semiconductor layer 6 and semiconductor layer 10 can provide carrier confinement due to bandgap differences with the active layer. For example, the bandgap of semiconductor layers 6 and 10 can be larger than the bandgap of one or more layers in the active layer 8 (e.g., quantum wells and/or barrier layers). Such a configuration can also ensure that layers 6 and 10 do not substantially absorb light emitted by active layer 8.

Active layer 8 can be a bulk layer or include one or more quantum wells that can be separated by barrier layers. Active layer 8 can be a single quantum well structure or a multiple quantum well structure (e.g., including two quantum wells, three quantum well, four quantum wells, etc.). In some embodiments, active layer 8 includes one or more ZnO-based semiconductors having bandgaps that can emit the desired wavelength of light under application of an electrical current to the light-emitting device (e.g., via device electrodes). In some embodiments, one or more ZnO-based semiconductors in the active layer (e.g., forming the quantum wells) have a bandgap of less than about 3 eV (e.g., less than about 2.8 eV, less than about 2.5 eV, less than about 2.3 eV) and thereby can generate visible light (e.g., violet light, blue light, and/or green light wavelengths) during device operation.

In some embodiments, the active layer 8 (e.g., quantum wells in the active layer) include a ZnO-based material including Cd, Se, and/or Te. Such elements can facilitate the modification (e.g., lowering) of the bandgap so as to provide a desired wavelength for the emitted light (e.g., visible light such as blue light). The Cd, Se, and/or Te atomic fraction can be less than about 0.3 and/or can be greater than about 0.05. Such alloys can enable visible light generation (e.g., ranging from about 400 nm to about 700 nm).

Barrier layers for the quantum wells can be formed of a material having a larger bandgap that the quantum wells, for example, any suitable ZnO-based material can be used that has such a bandgap. For example, ZnO itself or any suitable ZnO-based materials including Mg, Ca, Be, Sr, Ba, Cd, Se, Te, and/or S can be used as a barrier layer material for one or more of the quantum well barrier layers. Barrier layers can be p-type, n-type, and/or undoped.

In some applications, the active layer 8 include a ZnO-based material having a bandgap corresponding to UV light (e.g., UV-A, UV-B, or UV-C). For example, quantum wells can be formed with ZnO, ZnMgO, ZnBeO, ZnSrO and/or ZnCaO to produce light emission at or above the bandgap energy of ZnO (e.g., greater than about 3.37 eV). In such devices, semiconductor layer 6 and/or semiconductor layer 10 include a ZnO-based alloy having a higher bandgap than the ZnO-based material in the active layer (e.g., quantum wells in the active layer).

In some embodiments, active layer 8 can be textured. Such a textured active layer can lead to production of light having a broad wavelength spectrum. A broad wavelength spectrum in the visible range can be observable as white light to a human observer. In some embodiments, the textured active layer can lead to production of light having a wavelength spectrum with two or more wavelength peaks (i.e., local maxima in the wavelength spectrum). The two or more wavelength peaks can be observable as white light to a human observer. Texturing of the active layer can produce these effects due to variations in alloying composition and/or quantum well thickness on different crystallographic planes, edges, and/or vertices of the textured layer. These variations can result from the different growth rates and/or growth kinetics of different crystal planes. In some embodiments, active layer 8 can comprise first portions oriented along a first crystallographic plane and second portions oriented along a second crystallographic plane. In some embodiments, active layer 8 can further include third portions oriented along a third crystallographic plane. During device operation, active layer 8 can emit light having a plurality of peak emission wavelengths corresponding to emission from different crystallographic planes and/or intersections between different crystallographic planes (e.g., edges and/or vertices).

In some embodiments, the active layer 8, the n-type semiconductor layer and/or the semiconductor p-type layer (e.g., semiconductor layers 6 and 10) can be monocrystalline layers having a dislocation density of less than about 10⁶ cm⁻² (e.g., less than about 10⁵ cm⁻², less than about 10⁴ cm⁻², less than about 10³ cm⁻², less than about 10² cm²), as measured using etch pit density methods. Such a low dislocation density can be achievable as a result of the deposition of epitaxial layers having a composition that can be substantially lattice-matched to the substrate. The epitaxial layers can have a lattice mismatch with the substrate deposition surface of less than about 2.5% (e.g., less than about 2%, less than about 1%, less than about 0.5%, less than about 0.25%). For example, ZnO-based epitaxial layers, such as ZnO itself and/or ZnO-based alloys including Mg, Ca, Be, Sr, Ba, Cd, Se, Te, and/or S with a suitable atomic fraction, can be deposited on a ZnO substrate so as to achieve a low lattice mismatch with the substrate. Single crystal bulk ZnO substrates can have a dislocation density of less than about 10² cm⁻², as measured using etch pit density methods, thereby providing a low dislocation density baseline.

In some embodiments, a transparent conductive layer 12 is in electrical contact (e.g., disposed on) semiconductor layer 10. An electrode 14 can be disposed on the transparent conductive layer 12. Transparent conductive layer 12 can be disposed adjacent semiconductor layer 10 (e.g., the n-type semiconductor or the p-type semiconductor) and can provide current spreading from electrode 14 to semiconductor layer 10. Electrode 14 can be formed of any suitable metal that can provide electrical contact with transparent conductive layer 12. Electrode 14 can serve as an Ohmic electrical contact to the adjacent semiconductor (e.g., an adjacent oxide-based semiconductor). Examples of electrode metals or metal stacks include Ti/Au, Ti/Al, Ti/Al/Au, Ti/Al/Pt/Au, Cr/Au, Cr/Al, Cr/Al/Au, Al/Au, Al, Al/Pt, In, Ru or the like to form an n-type contact, and Ni/Al/Au, Ni/Ti/Au or the like to form a p-type contact. Part or all of electrode 14 can serve as an electrical contact pad (e.g., bond pad), to which a wire bond or a package metal trace can be attached (e.g., via solder or bump bonding) to provide an external electrical connection.

Transparent conductive layer 12 can be formed of one or more materials (e.g., ZnO-based materials) having a bandgap larger than the bandgap of the active layer or larger than the bandgap of quantum wells in the active layer, thereby minimizing the absorption of generated light. Transparent conductive layer 12 can be formed of one or more materials (e.g., ZnO-based materials) having a bandgap larger than the bandgap of semiconductor layer 6 and/or semiconductor layer 10 (e.g., cladding and/or contact layers of the light-emitting device).

In some embodiments, transparent conductive layer 12 can be formed of a transparent conductive oxide. Examples of transparent conductive oxides include ZnO-based materials, In₂O₃, indium tin oxide (ITO), or any combination thereof. In one embodiment, the transparent conductive layer 12 includes a ZnO-based material including In, Ga, and/or Al. The concentration of the In, Ga, and/or Al can range from dopant levels (e.g., greater than 10¹⁸ cm⁻³, greater than 10¹⁹ cm³, greater than 10²⁰ cm⁻³) to alloying atomic fractions (e.g., less than about 40%, less than about 20%, less than about 30%, less than about 10%), preferably between about 0.1% and about 10%. Transparent conductive layer 12 can have any suitable thickness, with a typical thickness ranging from between about 0.1 microns and about 3 microns, and a preferred thickness of about 1 microns. In some embodiments, the transparent conductive layer, such as a transparent conductive oxide, can have a thickness and absorption coefficient so as to exhibit light transmittance of greater than about 60% (e.g., greater than about 70%, greater than about 80%, greater than about 90%) at a wavelength emitted by the active layer. In some embodiments, the transparent conductive layer, such as a transparent conductive oxide, has a resistivity of less than about 10⁻² Ωcm (e.g., less than about 10⁻³ Ωcm) for an n-type layer and less than about 1 Ωcm (e.g., less than about 10⁻¹ Ωcm) for a p-type layer.

In some embodiments, transparent conductive layer 12 is formed of a monocrystalline transparent conductive oxide layer. The monocrystalline transparent conductive oxide layer can be formed of a ZnO-based material. The monocrystalline transparent conductive oxide layer can be disposed adjacent semiconductor layer 10 (e.g., the n-type semiconductor layer or the p-type semiconductor layer) and configured to provide current spreading to the semiconductor layer on which it is disposed. It should be appreciated that transparent conductive oxides are typically deposited as polycrystalline or amorphous films (e.g., via sputtering), whereas in some embodiments described herein, the transparent conductive oxide takes the form of a monocrystalline layer. Monocrystalline transparent conductive oxides, such as ZnO-based transparent conductive oxides, can be formed by epitaxial deposition processes, such as epitaxial deposition processes described herein. In some embodiments, a ZnO-based monocrystalline transparent conductive oxide include a monocrystalline ZnO-based compound including Al, In, and/or Ga. Such a monocrystalline transparent conductive oxide can have an n-type conductivity since Al, In, and/or Ga can act as donors for a ZnO-based material. In some embodiments, a ZnO-based monocrystalline transparent conductive oxide is a monocrystalline ZnO-based compound including K, Au, and/or Ag. Such a monocrystalline transparent conductive oxide can have a p-type conductivity since K, Au, and/or Ag can act as acceptors for a ZnO-based material.

In some embodiments, transparent conductive layer 12 includes a monocrystalline transparent conductive oxide layer having a dislocation density of less than about 10⁶ cm⁻² (e.g., less than about 10⁵ cm⁻², less than about 10⁴ cm⁻², less than about 10³ cm⁻², less than about 10² cm⁻²), as measured using etch pit density methods. Such a low dislocation density for a monocrystalline transparent conductive layer is achievable as a result of the deposition of epitaxial layers that are substantially lattice-matched to the substrate. The epitaxial layers can have a lattice mismatch with the substrate deposition surface of less than about 2.5% (e.g., less than about 2%, less than about 1%, less than about 0.5%, less than about 0.25%). For example, a ZnO-based transparent conductive layer having a suitable composition can be deposited on a ZnO substrate so as to achieve low lattice mismatch with the substrate.

In some embodiments, transparent conductive layer 12 can have a textured surface so as to facilitate light extraction. In some embodiments, transparent conductive layer 12 can comprise a textured monocrystalline layer. In some embodiments, the transparent conductive layer 12 can comprise a textured monocrystalline ZnO-based layer. The textured monocrystalline layer can be a textured monocrystalline transparent conductive oxide layer. A textured surface morphology of a layer, such as transparent conductive layer 12, can be formed during and/or after deposition of the layer, as described in further detail below.

Transparent conductive layer 12 can extend over the entire surface of semiconductor layer 10 or can extend over a portion of semiconductor layer 10. In some embodiments, a first portion of semiconductor layer 10 is covered by transparent conductive layer 12 and a second portion of semiconductor layer 10 is not covered by transparent conductive layer 12. For example, transparent conductive layer 12 can be arranged in a suitable geometrical layout, for example a grid layout, a cross layout, fingered layout, a interdigitated layout, or any other pattern.

Alternatively or additionally, a thin metal layer can be disposed over a portion or all of semiconductor layer 10 in any suitable geometrical layout and can serve as a current spreading layer. A bonding pad can be disposed over a portion of the thin metal layer. The thin metal layer can have a thickness of about 1 nm to about 100 nm and can be semi-transparent, preferably less than about 10 nm. The thin metal layer can be formed of a semi-transparent metal such as Pd, Pt, Pd/Au, Ni, NiO, Ni/NiO, Ni/Au, NiO/Au, or any other suitable metal(s) or any alloy thereof. Suitable metal layer(s) can be selected to provide an Ohmic contact with the adjacent semiconductor layer. For example, a thin semi-transparent metal layer including Ni, such as Ni, NiO, or NiO/Ni, can provide for an Ohmic contact with a p-type ZnO-based material layer. A thin semi-transparent metal layer including Ti and/or Cr can provide an Ohmic contact with an n-type ZnO-based material layer. In some embodiments, a thin metal layer can be disposed over a portion or all of transparent conductive layer 12.

Substrate 2 can be a ZnO, MgO, III-nitride (e.g., GaN, AN), sapphire, SiC, silicon, ScAlMg substrate, or any other suitable substrate. In some embodiments, the substrate can be a single crystal substrate. The substrate can be electrically conductive (e.g., n-type or p-type), optically transparent (e.g., to the wavelength of light emitted by the active layer and/or to all visible wavelengths), and/or thermally conductive. In some embodiments, the substrate comprises a ZnO-based material. Examples of such substrates include a ZnO single crystal substrate, a substrate including a layer of ZnO disposed on (e.g., deposited on and/or wafer bonded to) another material such as a sapphire base substrate or a glass base substrate, or any other substrate that includes a ZnO-based material.

In some embodiments, the substrate has a refractive index that is substantially the same (i.e., having a refractive index difference of less than about ±0.3) as the refractive index of the n-type semiconductor layer and the p-type semiconductor layers. In some embodiments, the substrate has a refractive index of greater than 1.9 at a light emission wavelength of the active layer. Such a substrate refractive index should be contrasted with the refractive index of a sapphire substrate, used for many GaN-based LEDs, that has a refractive index of about 1.8. In some embodiments, the substrate has a refractive index of less than 2.6 (e.g., less than about 2.3) at the light emission wavelength of the active layer. Such a substrate refractive index should be contrasted with the refractive index of SiC substrates, also used for GaN-based LEDs, that has a refractive index of about 2.7.

In some embodiments, the substrate can comprise a smooth surface over which the active layer, the n-type semiconductor layer and the p-type semiconductor layer are disposed. For example, a smooth surface can have a root-mean-square (RMS) roughness of less than about 5 nm (e.g., less than about 2 nm, less than about 1 nm).

The substrate can be electrically conductive thereby allowing the formation of a backside electrical contact via an electrode 16 disposed on the backside of the substrate 2. An electrically conductive substrate can be n-doped, p-doped, or compensated. The doping can be intentional or unintentional. Electrode 16 can be formed of one or more metals and can provide an electrical contact to substrate 2. Additionally, electrode 16 can also serve a reflective layer that can reflect light that can be emitted by the active layer and can impinge on the electrode. Alternatively or additionally, a distributed Bragg reflector (DBR), can be formed on the front-side and/or backside of the substrate 2. The DBR can be formed of a plurality of semiconductor, insulator, and/or conductive layers having difference refractive indices. For example, the DBR can be formed of a plurality of ZnO-based layers having different refractive indices, such as alternating layers of ZnO and/or ZnO-based alloys. Examples of ZnO-based alloys used to form the DBR include alloying elements such as Group II elements (e.g., Mg, Be, Ca, Sr, Ba, Cd, or other related elements), Group VI elements (e.g., Te, Se, S, or other related elements), other suitable elements, or combinations thereof.

Electrode 16 can serve as an Ohmic electrical contact to the adjacent semiconductor (e.g., an oxide-based semiconductor, such as a ZnO-based semiconductor). Electrode 16 include one or more reflective metal layers, such as a layer of Ag and/or Al, that can be in direct contact with the substrate backside, and one or more electrical contacting metal layer(s) that can be disposed on the reflective metal layer. The electrical contacting metal layer(s) can be formed of any suitable metal(s), such as Ti/Au or the like. In some embodiments, the backside of the substrate 2 can be textured (e.g., via methods described further below in relation to FIG. 6B) prior to the formation of a textured reflective layer, such as a textured metal layer, on the backside of the substrate 2. A textured reflective layer can frustrate total internal reflection in the semiconductor structure and facilitate light extraction.

As shown in FIG. 1A, the light-emitting device can possess at least one textured light emission surface 9 that is arranged to extract at least some of the light generated by the active layer. Enhanced light extraction via a textured surface can be due to frustration of total internal reflection within the structure. The textured light emission surface can be part of an electrically conductive or semiconductor layer, or electrically insulating or semi-insulating layer. In the case of a textured light emission surface that is part of an electrically conductive layer such as a semiconductor material layer, an electrode (e.g., electrode 14) can be formed thereover and the electrically conductive layer can provide for carrier transport through the device. In the case of a textured light emission surface that is part of an electrically insulating or semi-insulating layer, electrodes can extend through the electrically insulating or semi-insulating layer so as to make electrical contact with electrically conductive layers (e.g., semiconductor layers) under the textured light emission surface. In some embodiments, a textured light emission surface can be part of a textured monocrystalline layer, a textured nanostructured layer (e.g., nanowires, quantum dots), a textured polycrystalline layer, a textured amorphous layer, or any other suitable textured surface morphology.

In some embodiments, a textured light emission surface can be a surface of a layer disposed (e.g., deposited) on electrically conductive and/or semiconductor layers of the light-emitting device. For example, the textured light emission surface can be a topmost surface of an electrically insulating or semi-insulating layer deposited on electrically conductive and/or semiconductor layers. Alternatively or additionally, electrically conductive and/or semi-conducting layers of the light-emitting device can possess a textured light emission surface. For example, a topmost layer (e.g., epitaxial or otherwise) of the electrically conductive and/or semiconductor device layer stack can have a textured light emission surface.

During operation of a light-emitting device, such as the device of FIG. 1A, electrical power can be injected to the active layer 8 via electrodes 14 and 16. Electrons and holes can recombine radiatively at the active layer 8 thereby generating light, illustrated by dashed lines in the drawings. Light generated in the active layer can be emitted towards the textured light emission surface 9 or the electrode 16. Light impinging on the textured light emission surface 9 can be extracted at least partially via the textured light emission surface 9, and some of the impinging light can be reflected back. The backside reflective layer that can form part of electrode 16 can reflect the light back toward the textured light emission surface 9. The light can undergo multiple passes before extraction is complete. A majority of the generated light (e.g., greater than about 50%, greater than about 60%, greater than about 70%, greater than about 80%, greater than about 90%) can be extracted after multiple passes (e.g., less than about 6 passes, less than about 5 passes, less than about 4 passes, less than about 3 passes), and a remainder of the light can be absorbed within layers in the structure.

The device of FIG. 1A can be fabricated by depositing layers 6, 8, 10, and optionally also layer 12 on substrate 2. The deposition process include using conventional techniques such as chemical deposition techniques (e.g., MOCVD, plasma CVD) and/or physical deposition techniques (e.g., MBE). In a preferred embodiment, layers 6, 8, 10 and optionally also layer 12 are deposited in a single deposition process, such as an MOCVD or MBE process. Alternatively, when present, transparent conductor layer 12 can be deposited separately in another deposition system after the deposition of semiconductor layers 6, 8 and 10.

In one or more embodiments, ZnO-based materials can be formed as a crystalline thin film on a substrate, such as an epilayer deposited on a substrate. Epitaxial layers of ZnO-based materials can be deposited onto various substrates such as ZnO, MgO, III-nitride (e.g., GaN, AN), sapphire, SiC, silicon, or ScAlMg substrates. In some embodiments, the substrate can be a single crystal substrate.

A ZnO-based epilayer can be deposited using conventional techniques such as chemical deposition techniques (e.g., MOCVD, plasma CVD), physical deposition techniques (e.g., MBE, pulsed laser deposition, plasma assisted PLD) and the like. The ZnO-based material, in the form of an epilayer or otherwise, can be p-doped, n-doped, undoped, or compensated.

U.S. patent application Ser. No. 11/551,058, entitled “Zinc Oxide Based II-VI Compound Semiconductor Layers with Shallow Acceptor Conductivities and Methods of Forming Same,” which is hereby incorporated in its entirety by reference, discloses chemical vapor deposition fabrication techniques that enable the use of ZnO compounds in various applications. The fabrication techniques overcome difficulties relating to reliably fabricating p-type ZnO materials with sufficiently high concentrations of relatively shallow acceptor impurities operating as p-type dopants. The same methods used for p-type doping can also be used to prepare n-type ZnO by selection of the appropriate n-type dopants. An n-type ZnO can be prepared by using dopants including Al, Ga and In, or other appropriate elements. By way of example, ZnO can be doped with In at concentrations ranging from approximately 1×10¹² to 1×10²⁰ cm⁻³. The same fabrication techniques can be used to prepare n-type, p-type, undoped, and/or compensated ZnO alloys. In some embodiments, epitaxial layers of ZnO-based materials can be doped with p-type species such as Ag, Au and K and which can have as much as 50% acceptor activation in ZnO. In a similar manner, epitaxial layers of ZnO-based materials can be doped with n-type species such as aluminum, gallium or indium.

In some embodiments, the processing techniques for incorporating p-type dopants include implanting the silver, potassium and/or gold dopants into the ZnO-based compound semiconductor layer at dose levels of greater than about 1×10¹³ cm⁻² and, for example, in a range from about 1×10¹³ cm⁻² to about 1×10¹⁵ cm⁻². This implanting step can be performed as a single implanting step or as multiple implanting steps, which can be performed at multiple different implant energy levels to thereby yield multiple implant peaks within the layer. An annealing step is then performed to more evenly distribute and activate the dopants and repair crystal damage within the layer. This annealing step include annealing the ZnO-based compound semiconductor layer at a temperature in a range from about 250° C. to about 2000° C., in an ambient (e.g., chemically inert ambient) having a pressure in a range from about 25 mbar to about 7 kbar. In certain applications, it can be preferable to perform the annealing step at a temperature in a range from about 700° C. to about 700° C., in an oxygen ambient environment having a pressure of about 1 atmosphere. Similar ion implantation and anneal processes can be used for n-type dopants.

In some embodiments, a p-type ZnO-based compound semiconductor layer can be formed using an atomic layer deposition (ALD) technique, e.g. a deposition technique that includes exposing a substrate to a combination of gases. This combination include a first reaction gas containing zinc at a concentration that is repeatedly transitioned (e.g. pulsed) between at least two concentration levels during a processing time interval, and a second reaction gas containing oxygen and a p-type dopant gas containing at least one p-type dopant species selected from a group consisting of silver, potassium, gold, or an n-type dopant gas, as appropriate. A concentration of oxygen in the second reaction gas can be repeatedly transitioned between at least two concentration levels. In particular a concentration of zinc in the first reaction gas and a concentration of oxygen in the second reaction gas can be transitioned in an alternating sequence so that relatively high zinc concentrations in the first reaction gas overlap with relatively low oxygen concentrations in the second reaction gas and vice versa.

Methods of forming a p-type ZnO-based compound semiconductor layer can also include using an iterative nucleation and growth technique. This technique include using an alternating sequence of deposition/growth steps that favor c-plane growth (i.e., vertical growth direction, which causes nucleation) at relatively low temperatures interleaved with a-plane growth (i.e., horizontal growth direction, which causes densification) at relatively high temperatures to coalesce the layer. Iterative nucleation and growth include depositing a plurality of first ZnO-based compound semiconductor layers at a first temperature in a range from about 200° C. to about 600° C. and depositing a plurality of second ZnO-based compound semiconductor layers at a second higher temperature in a range from about 400° C. to about 900° C. These first and second ZnO-based compound semiconductor layers are deposited in an alternating sequence so that a composite layer is formed.

Still other methods of forming a p-type ZnO-based compound semiconductor layer include exposing the substrate to a combination of a first reaction gas containing zinc, a second reaction gas containing oxygen and a p-type dopant gas containing at least one p-type dopant species selected from a group consisting of silver, potassium and gold, while simultaneously transitioning a temperature of the substrate between at least two temperatures. These two temperatures include a first lower temperature in a range from about 200° C. to about 600° C. and a second higher temperature in a range from about 400° C. to about 900° C.

According to aspects of these embodiments, the concentration of the p-type dopant species in the p-type dopant gas is repeatedly transitioned between two concentration levels while the temperature of the substrate is also being transitioned between the two temperatures. In particular, the concentration of the p-type dopant species in the p-type dopant gas is transitioned in an alternating sequence relative to the transitioning of the temperature of the substrate so that relatively high concentrations of the p-type dopant species in the p-type dopant gas overlap with relatively low temperatures of the substrate and vice versa. Alternatively, the concentration of the p-type dopant species in the p-type dopant gas is transitioned so that relatively high temperatures of the substrate overlap with a timing of relatively high concentrations of the p-type dopant species in the p-type dopant gas.

In some embodiments, one or more ZnO-based compound semiconductor layer(s) can be formed on a substrate using a chemical vapor transport technique (e.g., MOCVD). This technique include transporting concentrations of a plurality of reaction gases in a carrier gas towards a substrate that is exposed to an ambient at growth temperature(s) between 300° C. and 1000° C. The pressure of the ambient is held in a range from about 20 Torr to about 76 Torr. By varying the reaction gases and/or their flow rates, one or more semiconductor layers (e.g., monocrystalline semiconductor layers) having desired compositions can be deposited on the substrate. Controlling the reaction can be used to control the thickness of each semiconductor layer. Reaction gases include diethylzinc for Zn, and oxygen gas for O. Alternative oxygen reaction gases include carbon dioxide, nitrous oxide, and/or nitrogen dioxide. Other reaction gases can be used for additional elements present in the desired semiconductor layer, such as cyclopentadiethylmagnesium for Mg, diethylcadmium for Cd, di-tertiary-butylselenium for Se, and other reaction gases known to those of ordinary skill in the art. Other reaction gases that can be employed include ethyl chloride as an n-type dopant gas of Cl, plasma N₂ or the like as a p-type dopant gas, or any other reaction gases known in the art for providing the desired elements for deposition.

In some embodiments, a condensed matter source can be used for some doping and/or alloying elements (e.g., Ag, Au, K) to circumvent limited availability of some volatile species using conventional metalorganic transport temperatures (e.g., ≦30° C.) and equipment. When using a condensed matter source, the source can be converted to a gas prior to transport. A condensed matter source include a source in a solid phase, a liquid phase or a semisolid phase, such as a gel. A bubbler or heater containing the condensed matter source can be heated to above room temperature in order to convert the source to the gas phase.

The condensed matter source can, preferably, include non-halogenated and non-silylated complexes, or include halogenated or silylated complexes. When using non-halogenated or non-silylated complexes, the material should have sufficient vapor pressure at reasonable elevated temperatures. For example, non-halogenated or non-silylated solid sources of Ag, Au and K can have a vapor pressure ranging from about 10⁻⁵ to about 10³ torr between about 30° C. and about 200° C. Generally, the sublimation of Au and K occurs at higher temperatures relative to Ag sublimation because of much lower volatility of their ligands.

Examples of some non-halogenated and non-silylated precursors that can be used for the source are listed below in Table 1 and some halogenated or silylated precursors that can be used are listed below in Tables 2 and 3, although others can be used.

TABLE 1
Non-halogenated and non-silylated precursors of Ag, Au and K

| Name | Variation |
|---|---|
| (R) silveracetylacetonate | R = Alkene and Alkyl |
| Silver Pivilate | |
| Silver trimethylacetate | |
| Dimethyl 1-2,4 pentadionate-Au | |
| (N,N″-diisopropylacetamindinato)Silver | Ag(i-PrNC(CH₃)N i-Pr) |
| Potassium Butoxide | |
| Triethylphosphine-Au-1-Diethyl- | |
| dithiocarbamate | |
| Dipivaloylmethanoatopotassium(KDPM) | |

TABLE 2
List of Halogenated or Silylated Silver and Gold Precursors

| Name | Variations | | |
|---|---|---|---|
| α-silver | α= | (β-diketonato) | |
| (bistrimethylsilyl) | | Hfac = hexafluoroacetyl | |
| acetylene | | Ttfac | |
| | | Btfac | |
| | | fod | |
| α-silver-vinyltriethlysilane | α= | Hfac | |
| α-silver-trialkylphosphine | α= | | (Cyclopentadienyl) |
| Ag (Cp)(PR₃) | | | (13-diketonato) |
| | | Hfac | |
| | | fod | |
| | | R= | Hydrocarbon e.g. |
| | | | Methyl group |
| | | | Ethyl group |

| | |
|---|---|
| Silver trifluoroacetate | Ag(COOCF₃) |
| Silver pentafluoropropionate | Ag(C₂F₅COO) and |
| | Ag(C₂F₅COO)PMe₃ |
| Dimethyl(1,1,1, trifluoro-2-4 | |
| pentadionate)Au | |
| Dimethyl(1,1,1-5,5,5, | |
| hexafluoro-2-4 | |
| pentadionate)Au | |
| Triethylphosphine-Au- | |
| Chloride | |

TABLE 3
List of Halogenated or Silylated Potassium Precursors

| Name | Variations |
|---|---|
| Potassium Hexafluorogermanante | K₂GeF₆ |
| Potassium Hexafluorosilicate | K₂SiF₆ |
| Potassium HexamethylDisilazide | KSi(CH₃)₃NSi(CH₃)₃ |
| Potassium Trimethlysilanolate | KOSi(CH₃)₃ |
| Potassium VinlyDImethlySilanolate | KOSi(CH₃)₂CHCH₂ |

For example, when using silver atoms for the p-type dopant and/or an alloying element, the vapor pressure of the silver-based condensed matter source or precursor can typically be between at least about 10⁻⁵ to 10³ torr. The conversion of the silver-based precursors can be achieved by heating the bubbler or heater that contains one or more selected compounds (e.g., compounds containing Ag, Au, or K) to at or above the compound's sublimation temperature, but below its decomposition temperature. For example, for some silver-based compounds, the sublimation temperature can be between about 30° C. to about 205° C. and the decomposition temperature can be between about 80° C. to about 300° C. For instance, when using silver trifluoroacetate (CF₃COOAg) as the precursor, the heater can be uniformly heated to an elevated temperature of about 60° C. (or higher) to ensure that significant vapor pressure of the precursor (e.g., ≧10⁻⁵ torr) is achieved even though the actual sublimation temperature of CF₃COOAg commences at around 30° C. in air. Similarly, when using silver trialkyphosphine-acetylacetonate (AcAcAgP₃) as the precursor, the heater can be heated to a temperature of about 180° C. (or higher) to ensure that significant vapor pressure of the precursor (e.g., ≧10⁻¹ torr) is achieved even though the actual sublimation temperature of AcAcAgP₃ commences at around 80° C. in air. As known to those skilled in the art, the sublimation temperatures can be marginally different in a vacuum.

To form a ZnO-based material layer, a reaction gas comprising zinc can be provided from a zinc-based source, a reaction gas comprising oxygen can be provided from an oxygen-based source, and other one or more other reactions gases supplying other elements (e.g., alloying and/or doping elements) desired in the ZnO-based material. The zinc-based source and the oxygen-based source are typically supplied in the gas phase, although the source can be in a solid, liquid, or semisolid phase.

Reaction gases including alloying and/or dopant atoms can be transported to one or more substrates located within a reactor chamber. As known to those skilled in the art, the substrate can be a wafer processed in a variety of ways and include a variety of materials. For ZnO-based films, the substrate preferably is a ZnO substrate (e.g., a single crystal ZnO substrate), although other materials can be used, as previously described.

Transport of gas species converted from condensed matter sources can be achieved by heating gas lines to an elevated temperature in order to limit or prevent condensation of the converted species during transport prior to delivery into a reactor chamber. The elevated temperature should be at least the minimum temperature of actual conversion/sublimation (e.g., 30° C. in the case of CF₃COOAg, 80° C. in the case of AcAcAgP₃) and preferably higher. For example, the elevated temperature gas lines can be maintained at approximately the same temperature as the bubbler (e.g., 60° C. in the case of CF₃COOAg, 180° C. in the case of AcAcAgP₃) or higher. For instance, the heated gas lines can be maintained at about 190° C. in the case of AcAcAgP₃.

An inert gas, such as argon, can be supplied into the heated bubbler through an inlet port via gas lines and allowed to exit through an outlet port into the heated gas lines. The inert gas can or can not be heated to an elevated temperature in gas lines prior to entering the heater. The elevated temperature gas transport lines can have valves and gauges that utilize special seals (e.g., such as polyimide and stainless steel), which can enable the flow regulation of the transported species within the temperature range of interest. Gas lines transport the second gas and the third gas, respectively, to the reactor chamber. The elevated temperature gas lines can be separate from the gas lines used from transporting the reaction gases of other elements (e.g., Zn and O₂) to prevent any premature reactions.

As is known by those skilled in the art, the deposition process can be conducted in the reactor chamber where the reaction gases can be combined. One or more additional gases can also be used, such as multiple organometallic precursors, reaction gases, inert carrier gases, etc.

Control of the process gas composition can be accomplished using mass-flow controllers, valves, etc., as known by those skilled in the art. The one or more substrates are typically heated to an elevated temperature in the reactor chamber. As the gases enter into the reactor, pyrolysis of the precursor complexes occurs either in the gas mixture or at the surface of the substrate when the gas mixture contacts the heated substrate surface. In some embodiments, such an MOCVD process can be used to deposit a ZnO-based semiconductor layer including Ag and/or Au with an atomic fraction greater than about 0.01 on one or more substrates.

In other embodiments, a ZnO-based compound semiconductor layer can be formed on a substrate using a molecular beam epitaxy technique. Using this technique, the desired elements to form the ZnO-based layer can be evaporated from one or more Knudsen cells to a substrate in a partial pressure of oxygen. For example, in the case of a ZnO-based material including Ag and/or Au elements (e.g., for doping and/or alloying), the Ag and/or Au can be evaporated from a first Knudsen cell concurrently with the evaporation of Zn from a second Knudsen cell in a partial pressure of oxygen. Additional Knudsen cell(s) can evaporate one or more other elements (e.g., Mg, Be, Ca, Sr, Ba, Cd, Te, Se, S, In, Al, Ga, or other elements) so as to form any desired ZnO-based material on the substrate. The temperature of the substrate is typically held at a temperature of greater than about 300° C. and at pressures ranging from about 25 mbar to about 700 mbar.

Still further embodiments include using a physical vapor transport technique that includes transport of zinc to a substrate by evaporation, magnetron sputtering, flame hydrolysis deposition or sublimation. Alternatively, liquid phase epitaxy techniques and solvus-thermal incorporation techniques can also be used to form the ZnO-based compound semiconductor.

The above-mentioned techniques can be employed to produce structures and devices that employ n-type, p-type, undoped, and/or compensated ZnO-based materials (e.g., ZnO-based epilayers). These techniques use processing conditions that can yield a net p-type dopant concentration of greater than about 1×10¹⁷ cm⁻³ therein, for dopants having an acceptor ionization energy below about 355 meV. The processing conditions can also yield a dopant activation level of greater than about 10% for the dopants having the desired acceptor ionization energy.

Returning to the fabrication processes for the device illustrated in FIG. 1A, metal layer(s) that can from electrode 16 can be deposited (e.g., evaporated and/or sputtered) on the backside of substrate 2. Metal layer(s) that can form electrode 14 can be deposited (e.g., evaporated and/or sputtered) on a patterned mask disposed on transparent conductive layer 12 (or semiconductor layer 10 when layer 12 is absent) that exposes a portion of the device surface. A lift-off process can be used to then form the electrode by selectively removing the mask. For example, a selective etch that etches the mask can be used to remove the mask and form electrode 14 covering a desired portion of the transparent conductive layer 12. Electrode 14 can cover an area of about 50 μm² to about 400 μm², with a preferred area being about 100×100 μm². A wafer including multiple die regions can be diced so as to form the die (chip) shown in the cross-section of FIG. 1A.

Various modifications to the above processes and device structure are possible. For example, substrate 2 can be lapped and optionally polished so as to reduce the thickness of the substrate (e.g., to a final thickness of about 100 microns) prior to deposition of the electrode on the backside. A reduced substrate thickness can minimize series resistance and/or substrate free carrier light absorption when using an electrically conductive substrate. Other variations are possible, such as any modification to the contacting geometry, for example modifications to the contacting geometry when using an electrically semi-insulating or insulating substrate.

FIG. 1B is a cross-sectional view of a light-emitting device similar to that of FIG. 1A, except that the transparent conductive layer 12 is absent. In such a configuration, current spreading across the chip area from the electrode 14 can be achieved via semiconductor layer 10 and/or via an extension of electrode 14 across a portion of the surface.

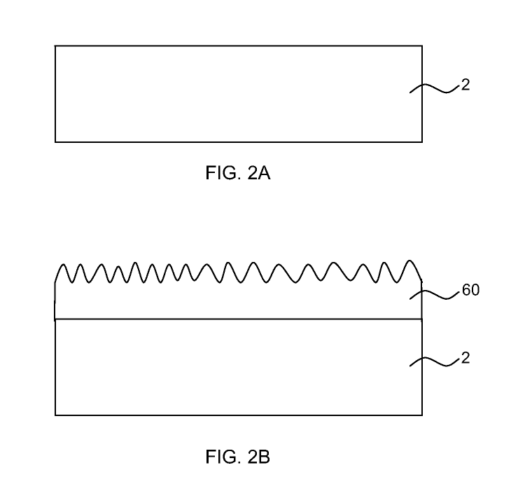

FIGS. 2A-B illustrate intermediate structures corresponding to a method for forming one or more textured layer(s) on a substrate. The process can be used to form light-emitting device structures, such as the light-emitting device structures illustrated in FIGS. 1A and 1B.

FIG. 2A is a cross-sectional via of a substrate provided for the deposition of a textured layer. The substrate 2 can be a ZnO, MgO, III-nitride (e.g., GaN, AN), sapphire, SiC, silicon, or ScAlMg substrate. In some embodiments, the substrate is a single crystal substrate. The substrate can have any crystal orientation so that the deposition surface exposes a desired crystal plane. In some embodiments, the substrate deposition surface is orientated such that the deposition surface is substantially non-polar (e.g., m-plane, a-plane). Alternatively, the substrate deposition surface is orientated such that the deposition surface is substantially semi-polar. In yet other embodiments, the substrate deposition surface is orientated such that the deposition surface is substantially polar (e.g., c-plane).

In some embodiments, the substrate has a hexagonal crystal structure (e.g., wurtzite). For example, the substrate can be a substrate having a ZnO-based or III-nitride surface layer or a ZnO-based or III-nitride single crystal substrate. The substrate can have a deposition surface oriented substantially parallel to a c-plane of the hexagonal crystal (e.g., with no off-cut or vicinal to the c-plane), which can provide for a substantially polar deposition surface. Alternatively, the substrate can be oriented substantially parallel to an m-plane or an a-plane of the hexagonal crystal (e.g., with no off-cut or vicinal to the m-plane or a-plane), which can provide for a substantially non-polar deposition surface. Alternatively, the substrate can be oriented substantially parallel to semi-polar crystal planes such as (11-10), (10-1-1), (10-12), (10-1-2), (11-2-1), (11-21), (11-2-2), and (11-22) planes or equivalent planes, which can provide for a semi-polar deposition surface.

In some embodiments, layer deposition conditions (e.g., temperature and/or reactant gas ratios) can result in the deposition of a textured layer on the substrate, as illustrated in the cross-sectional view of FIG. 2B showing a textured layer 60 deposited on substrate 2. In some embodiments, layer deposition conditions (e.g., substrate temperature and/or reaction gas supersaturation ratios) can create a textured monocrystalline layer. The textured layer can be a textured oxide semiconductor layer (e.g., a ZnO-based layer). The textured layer can be a textured monocrystalline oxide semiconductor layer, such as a textured monocrystalline ZnO-based layer. A textured monocrystalline layer should be distinguished from nano-crystalline layers formed of a multi-grain collection of nanostructures, such as nanorod or polycrystalline layers.

Regarding the deposition of a textured monocrystalline layer (e.g., a ZnO-based layer), the crystallographic orientation of the substrate deposition surface can influence the surface morphology of the deposited layer. For example, in the case of a wurtzite substrate (e.g., ZnO substrate), deposition on non-polar crystal planes, semi-polar crystal planes, or polar crystal planes can influence the surface morphology of the deposited layer.

In some embodiments, for a substrate having a ZnO deposition surface that is substantially non-polar (e.g., m-plane, a-plane, or vicinal planes thereof), a textured surface morphology for the deposited layer (e.g., a ZnO-based layer) can be achieved with substrate temperatures ranging from about 400° C. to about 600° C. A CVD process (e.g., MOCVD) can be used to deposit the textured layer. Supersaturation ratios of Group VI to Group II elements (VI/II) in the reaction chamber, such as oxygen to zinc (0/Zn) in the case of ZnO deposition, can range from about 50 to about 5000. As known by those skilled in the art, the supersaturation ratio can be derived from the molarity, the vapor pressure, or the flow rate of the gases. The above-mentioned deposition conditions allow for the formation of a textured monocrystalline ZnO-based layer. The in-plane separation between peaks of the textured surface can range from about 50 nm to about 1000 nm and can depend on the specific deposition conditions. Similar texturing of ZnO-based layers can also apply to semi-polar ZnO deposition surfaces.

For example, for non-polar (e.g., m-plane, a-plane, or vicinal surfaces thereof) ZnO deposition substrates, MOCVD substrate temperatures of about 480° C. and VI/II supersaturation ratios of about 425 produced a ZnO textured monocrystalline layer having in-plane separation between peaks of the textured surface ranging from about 100 nm to about 200 nm. For these deposition conditions, the textured surface had a laminar-like surface morphology.

In a further example, for non-polar (e.g., m-plane, a-plane, or vicinal surfaces thereof) ZnO deposition substrates, MOCVD substrate deposition temperatures of about 600° C. and VI/II supersaturation ratios of about 425 can produce a ZnO textured monocrystalline layers. For these deposition conditions, the textured surface also had a laminar-like surface morphology.

In yet another example, for non-polar (e.g., m-plane, a-plane, or vicinal surfaces thereof) ZnO deposition substrates, MOCVD substrate temperatures of greater than about 750° C. and VI/II supersaturation ratios of about 425 failed to nucleate a ZnO epitaxial film.

In contrast, substantially smooth surfaces can be formed on non-polar (e.g., m-plane, a-plane, or vicinal surfaces thereof) ZnO substrates for MOCVD substrate temperatures greater than about 600° C. and less than about 750° C. and VI/II supersaturation ratios of about 425.

Reactant chemistry can play an important role in determining the surface morphology of a deposited layer. Various reactant gases can contribute to the formation of a textured or substantially smooth deposited layers. In the case of ZnO-based layer deposition, various MOCVD reactant sources of oxygen include O₂, O₃, NO₂, N₂O, H₂O, CH₃COOH, other oxygen-including sources, or mixtures of such sources. The particular oxygen source(s) used in the deposition process can influence the surface morphology of the deposited layer (e.g., a ZnO-based layer).

For example, when utilizing an O₂, NO₂, or N₂O oxygen source gas with VI/II supersaturation ratios ranging from about 200 to about 400, the deposited ZnO-based layer exhibited a highly textured surface morphology. For these deposition conditions, the textured surface also had a patch-like surface morphology where the patches had hexagonal-like outlines.

When utilizing a mixture of O₂ and N₂O (e.g., mixture ratio of about 1:1) or a mixture of O₂ and NO₂ (e.g., mixture ratio of about 1:1) with VI/II supersaturation ratios ranging from about 200 to about 400, the deposited ZnO-based layer exhibited a substantially smooth surface morphology.

For deposition processes (e.g., MOCVD) where a ZnO deposition substrate has a substantially polar deposition surface (e.g., c-plane or vicinal surfaces thereof), a textured or smooth surface morphology for the deposited layer (e.g., a ZnO-based layer) can be achieved with a single-step or multiple-step deposition process. A multiple-step deposition process (e.g., MOCVD) include performing a first deposition step at a first temperature and a second deposition step at a second temperature higher than the first temperature, as previously described. The first and second deposition steps can then be repeated until a desired deposited layer thickness is achieved, as previously described for the iterative nucleation and growth process.

For deposition on a polar ZnO surface (e.g., c-plane or vicinal surfaces thereof), iterative nucleation and growth include depositing a plurality of first ZnO-based layers at a first substrate temperature in a range from about 200° C. to about 600° C. and depositing a plurality of second ZnO-based layers at a second higher substrate temperature in a range from about 400° C. to about 900° C. The first and second ZnO-based layers can be deposited in an alternating sequence so that a composite layer is formed. In some iterative nucleation and growth processes, the VI/II supersaturation ratios can range from about 50 to about 5000, and in some such embodiments, the VI/II supersaturation ratios can range from about 100 to 500.

For deposition on a polar ZnO surface (e.g., c-plane or vicinal surfaces thereof), a single-step deposition process (e.g., MOCVD) can involve performing a growth process for substrate temperatures ranging from about 650° C. to about 900° C., depending on reaction chemistry. When using an O₃ and/or NO₂ reaction gas, single-temperature deposition of ZnO-based layers can be performed at temperatures ranging from about 650° C. to about 900° C. When using an O₂ reaction gas, single-temperature deposition of ZnO-based layers can be performed at temperatures ranging from about 850° C. to about 900° C. Supersaturation ratios of Group VI to Group II elements (VI/II) in the reaction chamber, such as oxygen to zinc (O/Zn) in the case of ZnO deposition, can range from about 50 to about 5000, and in some such embodiments, the VI/II supersaturation ratios can range from about 100 to 500.

FIG. 2B illustrates the deposition of a layer 60 on a substrate 2. In the context of the device structures presented herein, layer 60 can represent one or more epitaxial layers deposited on any deposition surface, such as a substrate 2. For example, layer 60 can represent or more of the device layers of the devices illustrated in FIG. 1A or 1B. Furthermore, any combination of any suitable number of textured layer depositions and/or smooth layer depositions can be performed in any desired order. In some embodiments, a deposition process that can form smooth layers when performed on a smooth deposition surface can enable the formation of a textured layer when the growth is performed on a textured deposition surface which can be due to the conformal growth of the layer on the textured surface. In some embodiments, a deposition process that can form textured layers can increase the degree of texturing (e.g., as characterized by the RMS surface roughness, peak-to-valley height, or any other suitable roughness metric) when performed on a textured deposition surface.

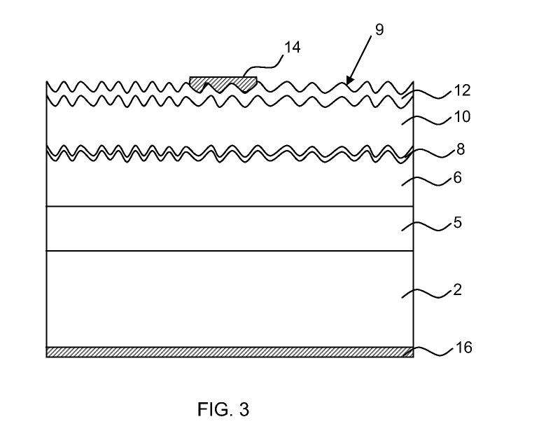

FIG. 3 is a cross-sectional view of a light-emitting device including one or more device layers deposited on a buffer. In some embodiments, the one or more device layers can be textured and the buffer can at least in part determine the surface morphology of the textured layers. The device illustrated in FIG. 3 is similar to that of FIG. 1A, except that a buffer 5 is present which can influence the surface morphology of the layer(s) deposited thereon. In particular, the surface chemistry and/or energy of the buffer 5 can impact the surface morphology of the layers deposited on the buffer 5, thereby influencing the degree and/or character of surface texturing for the deposited layers. The buffer influence on the surface morphology of layers deposited thereon include influence on the surface roughness, in-plane distance between surface peaks, depth of surface depressions, facet angles of surface peaks, and/or other surface morphology characteristics.

In some embodiments, the light-emitting device emits light with a wavelength spectrum having a plurality of peak wavelengths, and the surface morphology of the active layer at least partially determines the peak emission wavelengths. In such an embodiment, buffer 5 can be selected to at least partially influence the surface morphology of the active layer and hence the light emission spectrum of the light-emitting device.

In some embodiments, buffer 5 can be monocrystalline and thereby provide for suitable deposition surface on which monocrystalline layers can be epitaxially deposited thereon. Buffer 5 can be substantially lattice-matched to the underlying substrate so as to keep the dislocation density to a low. Buffer 5 can have a low dislocation density of less than about 10⁶ cm⁻² (e.g., less than about 10⁵ cm⁻², less than about 10⁴ cm⁻², less than about 10³ cm⁻², less than about 10² cm⁻²). The lattice mismatch between buffer 5 and the substrate deposition surface can be less than about 2.5% (e.g., less than about 2%, less than about 1%, less than about 0.5%, less than about 0.25%).

In some embodiments, buffer 5 include one or more oxide-based layers (e.g., metal oxide layers), such as one or more ZnO-based layers. Buffer 5 can substantially influence the surface morphology of layers deposited thereon. In some embodiments, buffer 5 include one or more layers comprising transition metals, for example transition metal oxides. Examples of transition metal oxides include oxides comprising Mn, Co, Mo, Fe, Ni, V, Cr, Ti, etc. such as ZnO-based materials including or more transition metals, such as ZnMnO, ZnCoO, ZnMoO, ZnFeO, ZnNiO, ZnVO, ZnCrO, ZnTiO or combinations thereof. The atomic fraction of the transition metal(s) in the buffer layers can range from dopant levels (e.g., greater than 10¹⁷ cm⁻³, greater than 10¹⁸ cm³, greater than 10¹⁹ cm⁻³, greater than 10²⁰ cm⁻³) to alloying fractions (e.g., less than about 40%, less than about 30%, less than about 20%, less than about 10%), preferably between about 0.1% and about 10%.

In some embodiments, buffer 5 include one or more layers comprising one or more Group III elements, for example one or more oxide layers, such as one or more Group III-oxide layers that can also include Zn (e.g., ZnAlO, ZnGaN, ZnInN, or alloys thereof). The atomic fraction of Group III elements in the buffer layers can range from dopant levels (e.g., greater than 10¹⁷ cm⁻³, greater than 10¹⁸ cm⁻³, greater than 10¹⁹ cm⁻³, greater than 10²⁰ cm⁻³) to alloying atomic fractions (e.g., less than about 40%, less than about 30%, less than about 20%, less than about 10%, less than about 5%), preferably between about 0.1% and about 10%. In some embodiments, buffer 5 include one or more nitride layers, such as one or more Group III-nitride layers (e.g., GaN, AlN, InN, or combinations thereof).

Buffer 5 can be electrically conductive or electrically non-conductive, and can be doped according to achieve desired electrical properties such as n-type or p-type conductivity. Buffer 5 can have a thickness of less than about 5 microns (e.g., less than about 2 microns, less than about 1 micron, less than about 500 nm, less than about 100 nm, less than about 10 nm). In some embodiments, the thickness of the buffer layer is less than the critical thickness for dislocation nucleation in the buffer layer. As is well known, the critical thickness depends on the lattice mismatch between the buffer layer and that of the underlying layer on which the buffer is deposited (e.g. the substrate).

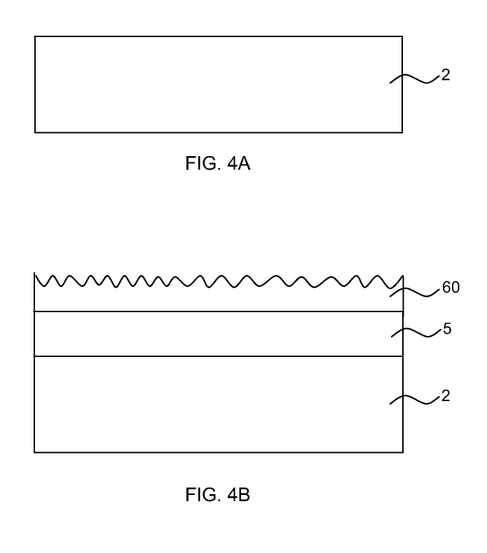

FIGS. 4A-B are cross-sectional views of intermediate structures corresponding to a method for forming one or more textured layer(s) on a buffer. The process can be used to form the light-emitting device structures (e.g., LEDs, laser diodes), such as the light-emitting device of FIG. 3A, however it should be appreciated that the structures and/or methods can be applied to other devices, such as other opto-electronic devices and electronic devices. Specific examples of such other devices include photovoltaics, transistors (e.g., FETs, HBTs), photo-detectors, excitonic devices and integrated circuits (e.g., optical switches).

The method of forming the device include depositing a buffer 5 on a substrate 2. Deposition of the buffer can be performed with a physical and/or chemical deposition process. In one embodiment, the deposition process includes a MOCVD process. In another embodiment, the deposition process includes a MBE process. In some embodiments, the buffer layer includes one or more oxide-based layers, for example one or more ZnO-based layers. In other embodiments, the buffer layer includes one or more nitride-based layers, for example one or more Group III-nitride layers (e.g., GaN, AlN, InN, or alloys thereof).

The substrate 2 can be a ZnO, MgO, III-nitride (e.g., GaN, AlN), sapphire, silicon carbide, silicon, or ScAlMg substrate. In some embodiments, the substrate is a single crystal substrate. The substrate can have any crystal orientation so that the deposition surface is parallel to a desired crystal plane. In some embodiments, the substrate deposition surface is substantially non-polar (e.g., m-plane or a-plane of a wurtzite crystal). Alternatively, the substrate deposition surface is substantially semi-polar. In yet other embodiments, the substrate deposition surface is substantially polar (e.g., c-plane of a wurtzite crystal).

After the buffer 5 deposition, at least one textured monocrystalline device layer 60 can be deposited on buffer layer 5. Deposition of textured monocrystalline device layer 60 can be performed with a physical (e.g., MBE) and/or chemical deposition process (e.g., MOCVD). The surface morphology of the textured monocrystalline device layer 60 can be at least partially determined by the buffer layer 5, for example the surface chemistry of the buffer layer 5. Other factors that can influence the surface morphology include the substrate temperature and/or the reactant gas chemistry.

In some embodiments, the least one textured monocrystalline device layer 60 is a layer of a light-emitting device. Device layers include an active layer, an n-type layer, a p-type layer, and/or a current spreading layer. The textured device can be a layer that includes a textured surface serving as light emission surface of the light-emitting device. In some embodiments, the device (e.g., light-emitting device) includes at least one ZnO-based layer that can be part of textured monocrystalline device layer 60. The device (e.g., light-emitting device) include a semiconductor structure including a plurality of ZnO-based layers, such as an n-type ZnO-based layer, a p-type ZnO-based layer, and an active layer disposed between the n-type layer and the p-type layer. The active layer can be formed of one or more ZnO-based layers. In some embodiments, the device (e.g., light-emitting device) includes at least one Group III-nitride materials (e.g., GaN, AN, InN, or combinations thereof). The device (e.g., light-emitting device) include a semiconductor structure including a plurality of one Group III-nitride layers, such as an n-type Group III-nitride layer, a p-type Group III-nitride layer, and an active layer disposed between the n-type layer and the p-type layer. The active layer can be formed of one or more one Group III-nitride layers.

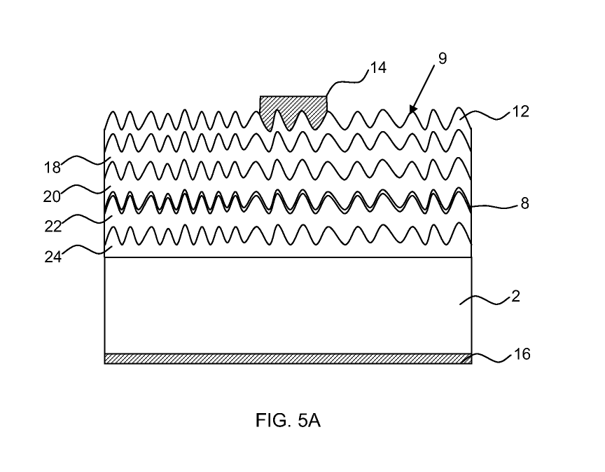

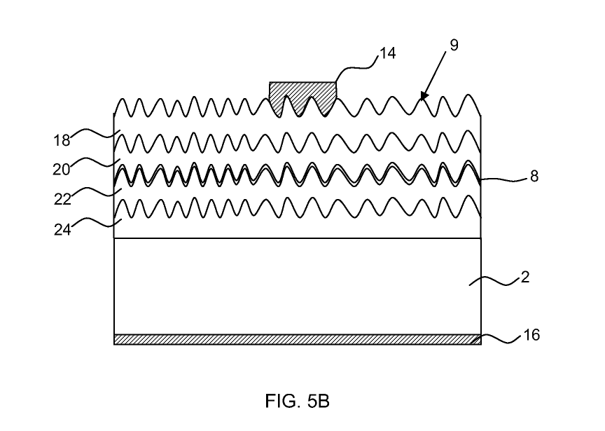

FIG. 5A is a cross-sectional view of a light-emitting device including semiconductor cladding and contact layers on one or both sides of the active layer. The device is similar to the light-emitting device of FIG. 1A except that semiconductor layer 6 can comprise a first conductivity-type (e.g., n-type or p-type) clad layer 22 and a first conductivity-type contact layer 24. Contact layer 24 can have a higher doping concentration than the clad layer 22, and can be formed of the same or different semiconductor materials. Semiconductor layer 10 can comprise a second conductivity-type (e.g., p-type or n-type) clad layer 20 and a second conductivity-type contact layer 18. Contact layer 18 can have a higher doping concentration than the clad layer 20, and can be formed of the same or different semiconductor materials. As described in relation to FIG. 1A, one or more of the device layers can be textured. In some embodiments, one or more of the device layers can be textured monocrystalline layers.

When the device is a laser diode, optical waveguide layers (not shown) can be included on either side of active layer 8, so as to provide lateral waveguiding of the light within the laser cavity. Such a configuration can be used in a side-emitting laser diode where the laser resonator cavity is oriented laterally along a length of the die. However, for other types of lasers, such as a vertical cavity emitting laser diodes (VCSELs), other configurations can be used and the above-mentioned optical waveguide layers on either side of the active layer can be omitted or modified. Distributed Bragg reflectors can be provided on one or both sides of the active layer to form a vertical laser cavity. Irrespective of the light-emitting device configuration, one or more of the ZnO-based materials taught herein can be incorporated in the device, for example in the active layer, clad layers, carrier confinement layers, and/or the contact layers.

FIG. 5B is a cross-sectional view of a light-emitting device similar to that of FIG. 5A, except that transparent conductive layer 12 is absent.

FIG. 6A is a cross-sectional view of a light-emitting device having a lateral electrical contacting geometry. The device is similar to that of FIG. 5A except that the backside substrate electrode 16 (of the device shown in FIG. 5A) is absent and electrical contact to a first conductivity-type contact layer 25 is achieved via electrode 15 that can be in direct contact with contact layer 25. For such an electrical contacting geometry, substrate 2 can be electrically conductive, semi-insulating, or insulating. Such a configuration can be flip-chip bonded onto a package sub-mount and electrical contact to the electrodes 14 and 15 can be achieved via bump bonding or any other appropriate contacting approach. Contact layer 25 can be textured or substantially smooth so as to facilitate etching and electrical contacting.

In some embodiments, first conductivity-type contact layer 25 include a monocrystalline transparent conductive oxide layer. The monocrystalline transparent conductive oxide layer can provide a low resistivity layer for lateral carrier transport. The monocrystalline transparent conductive oxide layer can be disposed between the substrate and the plurality of semiconductor layers including an n-type semiconductor layer, a p-type semiconductor layer, and the active layer. A monocrystalline transparent conductive layer, that can also have a low dislocation density, can ensure that epitaxial layers deposited thereon (e.g., n-type semiconductor layer, p-type semiconductor layer, active layer) are also monocrystalline and can also have low dislocation densities (e.g., less than about 10⁶ cm⁻², less than about 10⁵ cm⁻², less than about 10⁴ cm⁻², less than about 10³ cm²).

The device structure shown in FIG. 6A can be fabricated by performing a masked etch (e.g., dry etching and/or wet etching) of the semiconductor surface so as to expose contact layer 25 in a portion of each chip. Electrode 15 can be formed using metal deposition and a liftoff process, similar to processes that can be used to form electrode 14. A reflective layer 17 can be present on the backside of substrate 2, however, this layer need not necessarily serve as an electrode layer since the substrate can be electrically insulating. Alternatively or additionally, a distributed Bragg reflector (DBR), which can be formed of a plurality of oxide-based layers (e.g., metal oxide layers such as ZnO-based layers), can be disposed between active layer 8 and the substrate 2.

FIG. 6B is a cross-sectional view of a light-emitting device including a textured reflective layer. Electrode 14 can be formed over semiconductor layer 18 and include a textured reflective layer. The textured reflective layer can be formed of a metal reflective layer (e.g., Ag, Al, Au, or other suitable metals) and/or a distributed Bragg reflector (e.g., an oxide-based DBR, such as a ZnO-based DBR). Electrode 14 include other layers (e.g., one or more electrically conductive layers) that can serve other purposes, such as one or more electrical contact layers (e.g., disposed over the reflective layer) and/or diffusion barrier layers to restrict diffusion of elements to the surface of the reflective layer.

As shown in FIG. 6B, the light-emitting chip can be affixed to a package sub-mount 40 via a flip-chip configuration, also referred to as an epilayer-down configuration. The sub-mount 40 include electrically conductive traces (e.g., metal traces) 42 and 44. Electrodes 14 and 15 can be in electrical contact to electrically conductive traces 42 and 44, respectively. Electrical contact can be achieved via any suitable contacting approach, for example via metal bonding (e.g., bump bonding, solder bonding) layers 43 and 45, respectively. An electrically insulating material 46 or a void can be provided between electrodes 14 and 15. An epilayer-down configuration can also be utilized with a vertical contacting geometry, as opposed to the lateral contact geometry illustrated in FIG. 6B.

In some embodiments, the light-emitting device include one or more textured light emission surfaces. For example, FIG. 6B illustrates a light-emitting device including a textured substrate 1 (e.g., roughened and/or patterned) having a backside surface that serves as a light emission surface 9. Substrate 1 can comprise a first side on which the n-type and p-type semiconductor layers (e.g., layers 18, 20, 22, 25) and the active layer 8 are disposed and a second side opposing the first side, wherein the second side is textured. When a textured reflective layer (e.g., electrode 14) is incorporated into the device structure, the textured reflective layer can be arranged such that the semiconductor structure including the n-type layer, p-type layer, and active layer is disposed between the textured reflective layer (e.g., electrode 14) and the textured light emission surface 9 (e.g., the second side of the substrate).

Textured substrate 1 can be a ZnO, MgO, III-nitride (e.g., GaN, AlN), sapphire, SiC, silicon, or ScAlMg substrate. In some embodiments, the substrate can be a single crystal substrate. The substrate can be electrically conductive (e.g., n-type or p-type), optically transparent (e.g., to the wavelength of light emitted by the active layer and/or to all visible wavelengths), and/or thermally conductive. In some embodiments, the substrate comprises a ZnO-based material. Examples of such substrates include a ZnO single crystal substrate, a substrate including a layer of ZnO disposed on (e.g., deposited on and/or wafer bonded to) another material such as a sapphire base substrate or a glass base substrate, or any other substrate that includes a ZnO-based material.

One or more surfaces of the substrate could be textured (e.g., via a roughening etch and/or patterning) to facilitate light extraction via the one or more surfaces of the substrate. One or more of the other device layers can be textured or substantially smooth. Texturing of the substrate can be performed on a wafer level and/or on a die level (e.g., after the wafer has been diced).

When a ZnO substrate is utilized, a texturing etch that can be used to texture the substrate (e.g., the substrate backside) and/or the device die edges include HCl, a mixture of HCl and H₃PO₄, acetic acid, or mixtures thereof. In some embodiments, dilute HCl (e.g., HCl concentrations between about 0.1% and about 1% HCl in deionized water) can be used as a texturing etch. When using dilute HCl, etch times can range from about 5 seconds to about 2 minutes. Preferably, for a dilute HCl etch having an HCl concentration of about 0.5%, etch times can range from about 20 seconds to about 60 seconds. Addition of H₃PO₄ to the etch solution can provide increased surface texturing (e.g., increased peak-to-valley depth, increased RMS roughness). The textured substrate surface morphology include features (e.g., hexagonal features) such as pyramids and/or cones, where the features can have shapes at least partially determined by the crystal structure of the substrate material (e.g., hexagonal crystal). The surface features can have sidewall angles ranging from about 25 degrees to about 75 degrees, typically about 45 degrees.

FIG. 6C is a cross-sectional view of a light-emitting device including a plurality of textured light emission surfaces. In some embodiments, the light-emitting device include a textured front-side light emission surface 9a and an opposing textured backside light emission surface 9b, where the active layer 8 can be disposed between the textured front-side surface 9a and the textured backside surface 9b. In some embodiments, all sides of the light-emitting device (e.g., a front-side, a backside, and all edges of the light-emitting chip) serve as light emission surfaces. In some embodiments, the light-emitting device can be a ZnO-based light-emitting device (e.g., LED). The light-emitting device include one or more ZnO-based device layers, such as a ZnO-based p-type layer, a ZnO-based n-type layer, and/or a ZnO-based active layer, as was previously described (e.g., in relation to the device illustrated in FIG. 1A).

A reflector 50 can be located on one side of the light-emitting device so as to reflect light emitted from the surface of the device that faces the reflector 50. For example, in the device illustrated in FIG. 6C, the reflector 50 is a reflector cup disposed under the device backside. In some embodiments, the device can be oriented with epilayers oriented upwards, as illustrated in FIG. 6C. In other embodiments, the device can be oriented with epilayers oriented downwards, as in a flip-chip configuration, so that reflector 50 reflects light emitted from the front-side light emission surface 9a, as illustrated in FIG. 6E. Reflector 50 can have a diameter greater than about 3 times (e.g., about 5 times, about 10 times) the length of the chip. Reflector 50 can be a specular reflector, a diffuse reflector, or include portions of diffuse reflectivity and portions of specular reflectivity.

Supports 51 and/or 52 can provide structural support for the light-emitting device. Supports 51 and/or 52 can be composed of one or more substantially transparent materials, such that light emitted by the light-emitting device can be transmitted effectively through the supports. For example, support materials include a transparent ceramic. In some embodiments, supports 51 and/or 52 can be textured so as to facilitate extraction of any light that is transmitted into the supports. Leads 53 and 54 can be disposed on supports 51 and 52, respectively. Leads 53 and 54 can be formed of any electrically conductive materials, such as any metals (e.g., Al, Cu, Ag, Au, or combinations thereof). Wire bonds 55 and 56 can provide an electrical connection between leads 53 and 54 and electrodes 15 and 14, respectively.

In some embodiments, the light-emitting device can be encapsulated (not shown) with a suitable encapsulant material such as silicone, epoxy, and/or the like. The encapsulant could be in contact with a portion or the entire inside surface of reflector 50.

FIG. 6D is a top view of the light-emitting device of FIG. 6C. In the illustration, reflector 50 has a circular shape, however other shapes are possible such as a square, rectangular, or hexagonal shape.

FIG. 6E is a cross-sectional view of a light-emitting device including a plurality of textured light emission surfaces 9a and 9b and mounted in a flip-chip configuration. The device is similar to that illustrated in FIG. 6C, except for the flip-chip mounting arrangement.

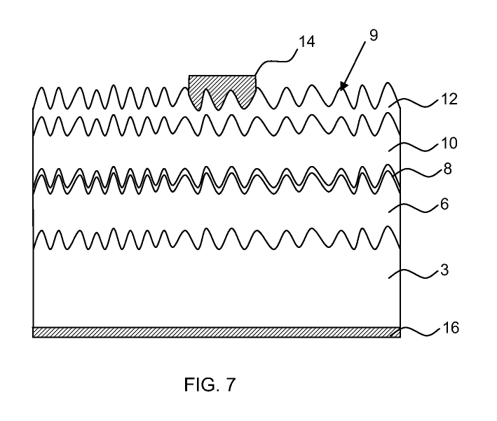

FIG. 7 is cross-sectional view of a light-emitting device including a substrate having a textured surface over which device epilayers can be deposited. Substrate 3 can comprise a textured surface over which the active layer, the n-type semiconductor layer and the p-type semiconductor layer can be disposed (e.g., deposited). The textured surface of substrate 3 can impart texture to the epilayers that are deposited on the textured surface.

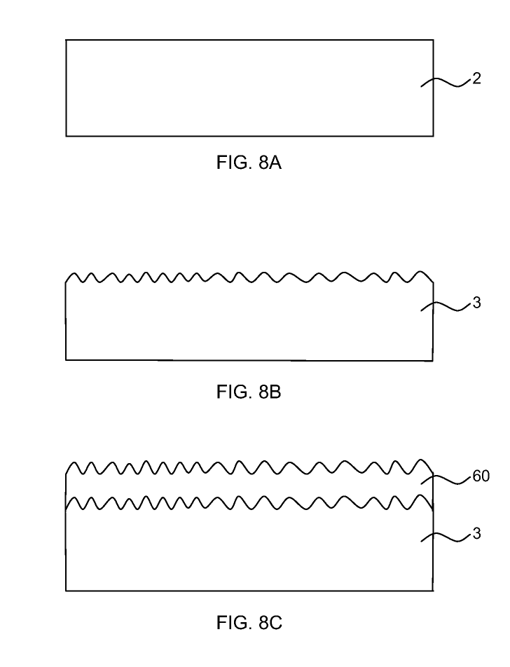

FIGS. 8A-C are cross-sectional views of intermediate structures corresponding to a method for forming one or more textured layers on a substrate having a textured deposition surface. The process can be used to form the light-emitting device structure of FIG. 7. FIG. 8A is cross-sectional view of a substrate 2 having a substantially smooth surface. The deposition surface of substrate 2 can then be textured resulting in a substrate 3 having a textured surface as shown in cross-sectional view of FIG. 8B. Alternatively, both the deposition surface and the backside of the substrate can be textured. Texturing of the substrate can be achieved via a texturing etch and/or patterning, such as providing a masking layer to selectively etch portions of a surface to provide texturing. For example, when a ZnO substrate is utilized, a texturing etch that can be used to texture the substrate, for example the backside of the substrate and/or the die edges, include a HCl, a mixture of HCl and H₃PO₄, acetic acid, or mixtures thereof.

FIG. 8C is a cross-sectional view of a resulting structure formed by the deposition of a textured layer 60 over the textured deposition surface of the textured substrate 3. In some embodiments, the textured layer can be a textured oxide semiconductor layer (e.g., a ZnO-based layer). In some embodiments, that textured layer can be a textured monocrystalline oxide semiconductor layer, such as a textured monocrystalline ZnO-based layer.

In the context of the device structures presented herein, layer 60 can represent one or more epitaxial layers deposited on any deposition surface, such as a substrate 3. For example, layer 60 can represent or more of the layers of the devices illustrated in FIG. 7. Deposition conditions that can form smooth layers when performed on a smooth deposition surface can enable the formation of a textured layer when the deposition process is performed on a textured deposition surface which can be due to the conformal growth of the layer on the textured surface of substrate 3. In some embodiments, a deposition process that can form textured layers can increase the degree of texturing (e.g., as characterized by the RMS surface roughness) when performed on the textured deposition surface of substrate 3.

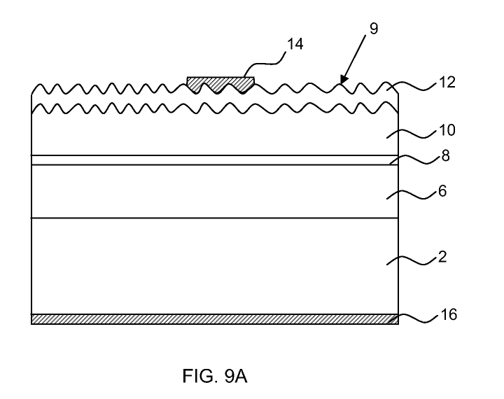

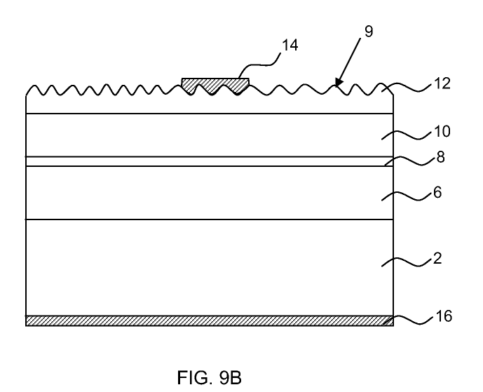

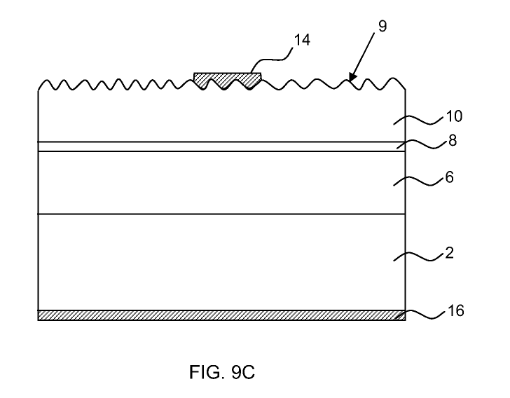

FIG. 9A is a cross-sectional view of a light-emitting device including a textured light emission surface 9. In some embodiments, semiconductor layer 10 and/or transparent conductive layer 12 can be textured. In some embodiments, active layer 8 can be substantially smooth. A light-emitting device having a substantially smooth active layer and a textured light-emission surface can provide for de-coupling of light generation in the active layer 8 and light extraction from the light-emitting device.

The device structure can be formed by depositing semiconductor layer 6 and active layer 8 using epitaxial deposition conditions that form substantially smooth layers, as previously described. Semiconductor layer 10 and/or transparent conductive layer 12 can be deposited using deposition conditions that form textured layers, as previously described above.

FIG. 9B is a cross-sectional view of a light-emitting device including a textured light emission surface 9. Here, semiconductor layer 10 can be substantially smooth and a textured layer (e.g., textured transparent layer, such as a textured transparent conductive layer 12) can be disposed on semiconductor layer 10. In some embodiments, the active layer 8 can be substantially smooth. The textured light emission surface 9 (e.g., textured surface of transparent conductive layer 12) can be formed by a deposition process that inherently forms textured layers and/or a texturing process (e.g., etching and/or patterning) can be utilized to texture the surface of the layer, as previously described. FIG. 9C is cross-sectional view of a light-emitting device including a textured light emission surface 9, absent a transparent conductive layer 12. Here, semiconductor layer 10 has a textured surface.

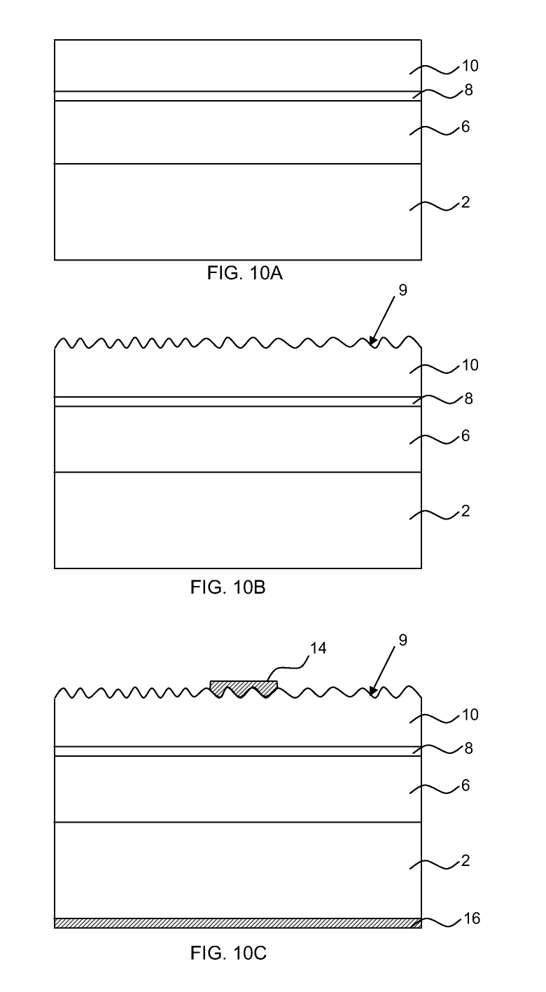

FIGS. 10A-C are cross-sectional views of intermediate structures corresponding to a method for forming a light-emitting device having a textured light emission surface 9. The process can be used to form the light-emitting device structures of FIG. 9C. FIG. 10A is cross-sectional view of a deposited structure including active layer 8 and semiconductor layers 6 and 10. In some embodiments, the deposited layers can be substantially smooth and texturing of a light emission surface can be performed after deposition, resulting in a textured surface 9 as illustrated in cross-sectional view of FIG. 10B. The textured surface 9 can be formed with a texturing process (e.g., etching and/or patterning) to texture the surface layer, as previously described. Electrode 16 can be formed on the backside of substrate 2 and electrode 14 can then be formed on the surface of semiconductor layer 10 as illustrated in cross-sectional view of FIG. 10C. Alternatively, a transparent conductive layer can be deposited on the surface of semiconductor layer 10 and can be textured to provide a textured light emission surface. In some embodiments, the backside surface of the substrate 2 can be textured prior to the formation of electrode 16. Texturing of the backside surface of substrate 2 can be achieved at the same time as the texturing of the topmost layer of the device structure, for example via a texturing etch of both sides of a wafer.

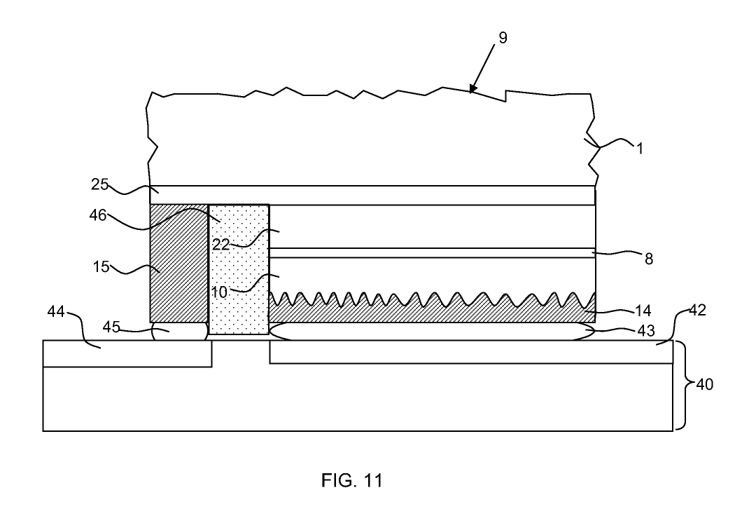

FIG. 11 is a cross-sectional view of a light-emitting device including a textured reflective layer. The device include an active layer 8 that can be substantially smooth. Electrode 14 can be formed over semiconductor layer 10 and include a textured reflective layer, as previously described. Electrode 14 include other layers (e.g., one or more electrically conductive layers) that can serve other purposes, such as one or more electrical contact layers (e.g., disposed over the reflective layer) and/or diffusion barrier layers to restrict diffusion of elements to the surface of the reflective layer. As shown in FIG. 11, the light-emitting chip can be affixed to a package sub-mount 40 via a flip-chip configuration. The light-emitting device include one or more textured light emission surfaces. For example, FIG. 11 illustrates a device having a textured substrate 1 (e.g., roughened and/or patterned) that serves as a textured light emission surface 9.

In some embodiments, a wavelength conversion material can be included in a light-emitting device and arranged so as absorb at least some light generated by the active region and emit light having a converted wavelength. For example, white light can be generated via wavelength conversion of some or all of the light (e.g., having a wavelength less than about 500 nm, such a blue, violet, and/or UV light) generated by the active region. The wavelength converting material include one or more phosphors and/or quantum dots, as is well known by those of skill in the art. The wavelength converting material can be combined with a binding material such as an encapsulant. In some embodiments, the wavelength converting material can be formed into a solid component (e.g., a solid plate, hemisphere, or any other suitable shape). The wavelength converting material component can be bonded to a light emission surface of the light-emitting device. One or more surfaces of the wavelength converting material component can be textured to from textured light emission surfaces that facilitate light extraction.

Various structures, devices, and processes provided herein are described in the context of ZnO-based materials and layers, however it should be appreciated that in some embodiments, any oxide-based material can be used, including but not limited to ZnO-based materials. In some embodiments, the oxide-based material can be an oxide semiconductor, including but not limited to ZnO-based semiconductors. In some embodiments, the oxide-based material can be a metal oxide material, such as a metal oxide semiconductor, including but not limited to ZnO-based semiconductors.

Although many of the structures and methods provided herein are described in the context of light-emitting devices (e.g., LEDs, LDs), these structure and methods can be applied to other devices, such as other opto-electronic, photonic, and electronic devices. Such devices include photovoltaics, transistors (e.g., FETs, HBTs), photo-detectors, excitonic devices and integrated circuits (e.g., optical switches). These devices include one or more textured layers, such as textured light emission and/or collection surfaces, textured active layers, and/or textured reflective layers. Some devices include textured monocrystalline layers. The devices include one or more monocrystalline transparent conductive oxide layers, which can be textured. In some such devices, ZnO-based materials can be employed to form part or the entire semiconductor portion of the device. Furthermore, in some instances a ZnO substrate can be used to provide a substrate on which semiconductor layers can be deposited.

As used herein, when a structure (e.g., layer, region) is referred to as being “on”, “over” “overlying” or “supported by” another structure, it can be directly on the structure, or an intervening structure (e.g., layer, region) also can be present. A structure that is “directly on” or “in contact with” another structure means that no intervening structure is present. A structure that is “directly under” another structure means that no intervening structure is present.

As used herein, when a structure (e.g., layer, region) is referred to as being “textured” or having “texture” the inventors intend to convey surface roughness within the parameters specified in this specification and as understood by one of ordinary skill in the art.

The terms “an embodiment”, “embodiment”, “embodiments”, “the embodiment”, “the embodiments”, “an embodiment”, “some embodiments”, and “one embodiment” mean “one or more (but not all) embodiments of the present invention(s)” unless expressly specified otherwise.

The terms “including”, “having,” “comprising” and variations thereof mean “including but not limited to”, unless expressly specified otherwise.

The term “consisting of” and variations thereof mean “including and limited to”, unless expressly specified otherwise.

The enumerated listing of items does not imply that any or all of the items are mutually exclusive. The enumerated listing of items does not imply that any or all of the items are collectively exhaustive of anything, unless expressly specified otherwise. The enumerated listing of items does not imply that the items are ordered in any manner according to the order in which they are enumerated.

The terms “a”, “an” and “the” mean “one or more”, unless expressly specified otherwise.

Headings of sections provided in this patent application and the title of this patent application are for convenience only, and are not to be taken as limiting the disclosure in any way.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A semiconductor device comprising:
a first ZnO-based semiconductor layer;
a second ZnO-based semiconductor layer;
a third ZnO-based semiconductor layer,
wherein the second layer is disposed between the first layer and the third layer, and
wherein the first layer and the third layer have a larger energy bandgap than at least a portion of the second layer; and
at least one contiguous textured light emission surface.

2. The semiconductor device of claim 1, further comprising a ZnO-based substrate on which the first layer, the second layer, and the third layer are disposed.

3. The semiconductor device of claim 1, wherein the at least one contiguous textured light emission surface is disposed over at least a portion of the second layer.

4. The semiconductor device of claim 1, wherein the at least one contiguous textured light emission surface contains at least one non-granular layer.

5. The semiconductor device of claim 4, wherein the at least one non-granular layer is a ZnO-based layer.

6. The semiconductor device of claim 1, wherein the at least one contiguous textured light emission surface contains a monocrystalline layer.

7. The semiconductor device of claim 6, wherein the monocrystalline layer is a ZnO-based layer.

8. The semiconductor device of claim 1, wherein the at least one contiguous textured light emission surface contains an amorphous layer.

9. The semiconductor device of claim 8, wherein the amorphous layer is a ZnO-based layer.

10. The semiconductor device of claim 1, wherein the second layer is an active layer of a light emitting device.

11. The semiconductor device of claim 10, wherein the active layer is oriented substantially parallel to a non-polar plane of a ZnO-based semiconductor forming the second layer.

12. The semiconductor device of claim 10, wherein the active layer is oriented substantially parallel to a semi-polar plane of a ZnO-based semiconductor forming the second layer.

13. The semiconductor device of claim 10, wherein the active layer is oriented substantially parallel to a polar plane of a ZnO-based semiconductor forming the second layer.

14. The semiconductor device of claim 1, wherein the first layer is an n-type ZnO-based semiconductor layer and the third layer is a p-type ZnO-based semiconductor layer.

15. The semiconductor device of claim 1, wherein the second layer is a monocrystalline ZnO-based semiconductor layer.

16. The semiconductor device of claim 1, wherein the third ZnO-based semiconductor layer is a contiguous textured light emission surface.

17. A semiconductor device comprising:
a substrate comprised of a ZnO-based material;
a structure disposed on a first side of the substrate, the structure comprising a plurality of semiconductor layers and an active layer disposed between the plurality of semiconductor layers; and
at least one contiguous textured light emission surface.

18. The semiconductor device of claim 17, wherein the active layer is a ZnO-based semiconductor layer.

19. The semiconductor device of claim 18, wherein the active layer is oriented substantially parallel to a non-polar plane of the ZnO-based semiconductor.

20. The semiconductor device of claim 18, wherein the active layer is oriented substantially parallel to a semi-polar plane of the ZnO-based semiconductor.

21. The semiconductor device of claim 18, wherein the active layer is oriented substantially parallel to a polar plane of the ZnO-based semiconductor.

22. The semiconductor device of claim 17, wherein at least one of the plurality of semiconductor layers is an n-type ZnO-based semiconductor layer.

23. The semiconductor device of claim 17, wherein at least one of the plurality of semiconductor layers is a p-type ZnO-based semiconductor layer.

24. The semiconductor device of claim 17, wherein each of the plurality of semiconductor layers is a ZnO-based semiconductor layer.

25. The semiconductor device of claim 17, wherein the at least one contiguous textured light emission surface is a ZnO-based layer.

26. The semiconductor device of claim 17, wherein the at least one contiguous textured light emission surface is a monocrystalline layer.

27. The semiconductor device of claim 26, wherein the monocrystalline layer is ZnO-based layer.

28. The semiconductor device of claim 17, wherein the at least one contiguous textured light emission surface is an amorphous layer.

29. The semiconductor device of claim 28, wherein the amorphous layer is ZnO-based layer.

30. The semiconductor device of claim 17, wherein the semiconductor device is a light-emitting device.

31. A semiconductor device comprising:
a first ZnO-based semiconductor layer;
a second ZnO-based semiconductor layer;
a third ZnO-based semiconductor layer, wherein the second layer is disposed between the first layer and the third layer, and wherein the first layer and the third layer have a larger energy bandgap than at least a portion of the second layer; and
at least one non-granular textured light emission surface.

32. The semiconductor device of claim 31, wherein the at least one non-granular textured light emission surface is a ZnO-based semiconductor layer.

33. A semiconductor device comprising:
a first ZnO-based semiconductor layer;
a second ZnO-based semiconductor layer;
a third ZnO-based semiconductor layer, wherein the second layer is disposed between the first layer and the third layer, and wherein the first layer and the third layer have a larger energy bandgap than at least a portion of the second layer; and
at least one non-columnar textured light emission surface.

34. The semiconductor device of claim 33, wherein the at least one non-columnar textured light emission surface is a ZnO-based semiconductor layer.

35. A method of forming a device, the method comprising:
depositing a buffer layer on a ZnO-based substrate;
depositing a first ZnO-based semiconductor layer,
the first ZnO-based semiconductor layer in direct contact with at least a portion of the buffer layer;
depositing a second ZnO-based semiconductor layer,
the second ZnO-based semiconductor layer in direct contact with at least a portion of the first ZnO-based semiconductor layer;
depositing a third ZnO-based semiconductor layer,
the third ZnO-based semiconductor layer in direct contact with a portion of the second ZnO-based semiconductor layer; and
depositing at least one textured contiguous light emission surface,
the at least one textured contiguous light emissions surface in direct contact with at least a portion of the third ZnO-based semiconductor layer.

36. The product produced by the method of claim 35.

37. The method of claim 35, wherein the at least one textured contiguous light emission surface is textured after deposition.

38. The product produced by the method of claim 37.

39. The method of claim 35, wherein the first ZnO-based semiconductor layer is a p-type ZnO-based semiconductor layer.

40. The method of claim 35, wherein the first ZnO-based semiconductor layer is an n-type ZnO-based semiconductor layer.

41. The method of claim 35, wherein each of the first, second and third second ZnO-based semiconductor layers is deposited parallel to a non-polar plane of the ZnO-based substrate.

42. The product of the method of claim 41.

43. The method of claim 35, wherein each of the first, second and third second ZnO-based semiconductor layers is deposited parallel to a semi-polar plane of the ZnO-based substrate.

44. The product of the method of claim 43.

45. The method of claim 35, wherein each of the first, second and third second ZnO-based semiconductor layers is deposited parallel to a polar plane of the ZnO-based substrate.
